(19) United States
(12) Patent Application Publication
(10) Pub. No.: US 2021/0292472 A1
(43) Pub. Date: Sep. 23, 2021

(54) Photosensitive Resin Composition

(71) Applicant: Nippon Kayaku Kabushiki Kaisha, Tokyo (JP)

(72) Inventors: Kiwamu Terada, Tokyo (JP); Hirokazu Kuwabara, Tokyo (JP)

(21) Appl. No.: 17/257,621

(22) PCT Filed: Jul. 2, 2019
(86) PCT No.: PCT/JP2019/026215

§ 371 Date: Jan. 4, 2021

(30) Foreign Application Priority Data
Jul. 5, 2018 (JP) 2018-127938
Mar. 13, 2019 (JP) 2019-045686

(51) Int. Cl. C08G 59/40

(52) U.S. Cl. CPC C08G 59/4007

(57) ABSTRACT

A novel compound which absorbs long-wavelength active energy rays and generates with high-efficiency radicals and strong bases, and which has excellent reaction efficiency in a base generating chain reaction; a photopolymerization initiator which contains said compound; and a photosensitive resin composition which contains said photopolymerization initiator are provided, where the novel compound is represented by formula (1), where, in formula (1), R₁, R₂, R₃, R₅ and R₆ independently represent a hydroxyl group, an alkoxy group, or an organic group other than those substituents, the R₄'s independently represent an organic group including a thioether bond, ‘A’ represents a substituent represented by formula (1-1) or (1-2), where, in formula (1-1), R₇ and R₈ independently represent a hydrogen atom, an alkyl group or a heterocyclic group, and where, in formula (1-2), R₉ and R₁₀ independently represent an amino group or a substituted amino group.

### CROSS-REFERENCE TO RELATED APPLICATIONS

This application is the United States national phase of International Application No. PCT/JP2019/026215 filed Jul. 2, 2019, and claims priority to Japanese Patent Application Nos. 2018-127938 filed Jul. 5, 2018 and 2019-045686 filed Mar. 13, 2019, the disclosures of which are hereby incorporated by reference in their entirety.

### BACKGROUND OF THE INVENTION

### Field of the Invention

The present invention relates to an alkali developing resin composition containing the photopolymerization initiator having the specific structure and capable of pattern forming by developing, a dry film obtained from the said resin composition, a cured product of the said resin composition and a printed wiring board having the said cured product.

### Description of Related Art

Recently in consideration of environmental problems, an alkali developing photosetting resin composition using an alkali aqueous solution as a developer is mainly used as a material of the solder resist for a printed wiring board or a flexible printed wiring board. Generally, the epoxy acrylate modified resin (hereinafter sometimes abbreviated to epoxy acrylate) induced by modifying an epoxy resin is used for such alkali developing type photosetting resin composition.

As shown in Patent Literature 1 and 2, the solder resist using such photosetting resin composition generally contains an alkali-soluble epoxy acrylate and an epoxy compound as a thermal curing component. By being subjected to the irradiation of the light and the thermal curing reaction after the irradiation, the cured product can be obtained.

In the photosetting resin composition, a thermal curing catalyst is generally used together so that the epoxy group can react completely during thermal curing or so that the temperature or the time for heating after the irradiation of the light can be reduced. However, because the pot life is short when the epoxy acrylate, the epoxy compound and the thermal curing catalyst are coexistent, two different liquid containing these components separately need to be made into one liquid just before using. Therefore, in addition to the problems that the process for the measurement or the mixing is complicated, there is also the problem that the pot life is short after two different liquid are made into one liquid.

In such a situation, the epoxy resin composition made into one liquid beforehand is demanded. Examples of the curing agent usable for one-liquid type epoxy resin composition include a dicyandiamide and an organic acid hydrazide. However, because both of these curing agents are solid-dispersible curing agents exhibiting latency by its insolubility in the epoxy resin, the technique to disperse the curing agent uniformly in the epoxy resin is needed, and also there is a problem that the epoxy resin composition containing the solid-dispersible curing agent cannot be used for adhering or sealing to the gap which is narrower than the curing agent particle diameter.

Also, the photosetting resin composition containing the thermal curing catalyst shown in Patent Literature 3 and 4 has poor storage stability in one-liquid state, namely the reaction progresses little by little even at room temperature to increase the viscosity gradually. Therefore, the thermal curing catalyst has to be mixed just before the work, but the problem that working efficiency is poor occurs.

The photosetting resin composition is required to have characteristics that the pot life is long after being made into one liquid and that the cured product therefrom is excellent in the physical and the electric properties obtained by heating after the irradiation of the light.

### CITATION LIST

### Patent Literature

Patent Literature 1: JP 2016-212258 A
Patent Literature 2: JP 2016-38587 A
Patent Literature 3: JP 2018-36651 A
Patent Literature 4: JP 5,852,633 B

### Non-Patent Literature

Non-Patent literature 1: “Network polymer” Vol. 35 No. 4 (2014)

### SUMMARY OF INVENTION

### Technical Problem

One of the purposes of the present invention is to provide the resin composition that exhibits a high storage stability in one liquid state and provides the cured product exhibiting excellent physical properties or electric properties.

### Solution to Problem

By the earnest research, the present inventors found to solve the problems by using the resin composition containing the photopolymerization initiator containing the compound of the specific structure, an alkali-developable resin, and a thermally reactive compound so as to finish the present invention.

That is, the present invention relates to:

[1] A resin composition comprising (A) a photobase generator containing a compound represented by a following chemical formula (1):

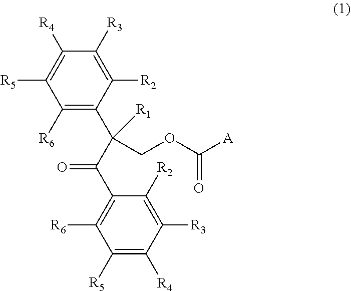

wherein in a formula (1), R₁ represents a hydrogen atom, a hydroxy group, an alkoxy group or an organic group other than the aforementioned substituents; R₂, R₃, R₅ and R₆ each independently represent hydrogen atom, halogen atom, hydroxy group, alkoxy group, mercapto group, sulfide group, silyl group, silanol group, nitro group, nitroso group, cyano group, sulfino group, sulfo group, sulfonato group, phosphino group, phosphinyl group, phosphono group, phosphonato group, amino group, ammonio group or an organic group other than the aforementioned substituents, each of R₂, R₃, R₅ and R₆ plurally existing may be the same or different from each other; R₂ and R₃ on the same benzene ring may be connected to form a ring structure and R₅ and R₆ on the same benzene ring may be connected to form a ring structure; R₄ each independently represents a hydrogen atom or an organic group having a thioether bond, and at least one of R₄ is the organic group having a thioether bond; the organic group having a thioether bond represented by R₄ and R₃ or R₅ may be connected to form a ring structure; A is a substituent having a formula (1-1) or (1-2):

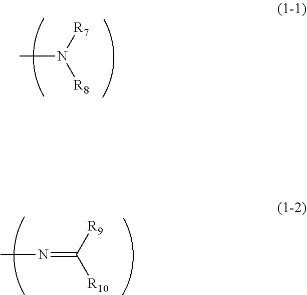

wherein in formula (1-1), R₇ and R₈ each independently represent a hydrogen atom or an alkyl group or a heterocyclic group, or R₇ and R₈ may be connected to form a heterocyclic ring; in formula (1-2), R₉ and R₁₀ each independently represent an amino group or a substituted amino group, (B) an alkali developable resin, and (C) a thermally reactive compound.
[2] The resin composition according to [1], wherein the resin composition can provide negative pattern formed by conducting alkali-developing after selective irradiation of the light and subsequent heating to the resin composition to provide addition reaction of (B) the alkali developable resin with (C) the thermally reactive compound
[3] A dry film obtained from the resin composition according to [1] or [2].
[4] A cured product of the resin composition according to [1] or [2].
[5] A cured product of the dry film according to [3].
[6] A printed wiring board comprising the cured product according to [4] or [5].

### Effects of the Invention

The compound represented by formula (1) which is contained in the photobase generator contained in the resin composition of the present invention is able to produce a base and a radical by the irradiation of the active energy ray. Because the compound is thermally stable without irradiation of the active energy ray, the increase of viscosity can be suppressed even under the prescribed temperature conditions. In addition, the compound has excellent storage stability even in the storage for a long time, when the compound is dissolved into one liquid. Furthermore, the produced base is the amine having high base strength or working as a base catalyst, which provides high quantum yield of cleavage. Therefore, when the thermal curing is conducted after the irradiation of the light, the cured product having the physical and the electric properties which are the same as the cured product obtained by a thermal curing catalyst used conventionally is obtained. The resin composition of the present invention containing the said compound is useful as a resist material which can be developed finely with an alkali developer and be applied to the build-up layer for a printed wiring board etc.

### BRIEF DESCRIPTION OF DRAWINGS

FIG. 1 shows the evaluation results of the storage stability of the resin composition solution at a temperature of 50° C.

FIG. 2 shows the evaluation results of the storage stability of the dry film obtained from the resin composition at a temperature of 25° C. and a humidity of 60%.

FIG. 3 shows the evaluation results of the storage stability of the dry film obtained from the resin composition at 10° C.

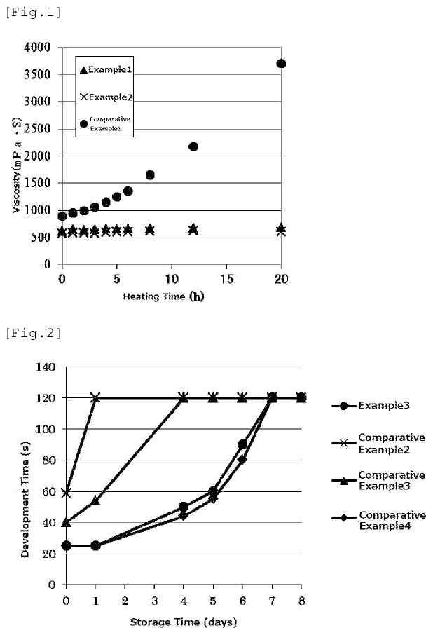

### DESCRIPTION OF THE INVENTION

The present invention is described below in detail. Note that examples of the active energy ray in the present invention include particle rays such as electron rays, and radical rays or ionization radiation which are generic terms of electromagnetic waves and particle rays in addition to visible light, provided that the case where a wavelength is specified is excluded. In this specification, the irradiation of the active energy ray may be referred to as exposure. Also, note that the active energy ray of a wavelength of 365 nm, 405 nm and 436 nm may be transcribed into i-ray, h-ray, and g-ray, respectively.

### <(A) Photobase Generator>

The resin composition of the present invention contains (A) the photobase generator containing the compound represented by formula (1).

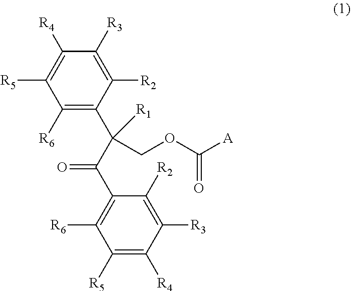

In formula (1), R₁ represents, a hydrogen atom, a hydroxy group, an alkoxy group or an organic group other than the aforementioned substituents.

The alkoxy group represented by R₁ in formula (1) is preferably an alkoxy group having a carbon number of 1 to 18. Examples of the alkoxy group include methoxy group, ethoxy group, n-propoxy group, iso-propoxy group, n-butoxy group, iso-butoxy group, sec-butoxy group, t-butoxy group, n-pentoxy group, iso-pentoxy group, neo-pentoxy group, n-hexyloxy group and n-dodecyloxy group.

Examples of the organic group represented by R₁ of formula (1) include an alkyl group having a carbon number of 1 to 18, an alkenyl group having a carbon number of 2 to 18, an alkynyl group having a carbon number of 2 to 18, an aryl group having a carbon number of 6 to 12, an acyl group having a carbon number 1 to 18, an aroyl group having a carbon number of 7 to 18, a nitro group, a cyano group, an alkylthio group having a carbon number of 1 to 18 and halogen atom.

Examples of the alkyl group having a carbon number of 1 to 18 described as the organic group represented by R₁ of formula (1) include a linear or branched alkyl group such as methyl group, ethyl group, n-propyl group, isopropyl group, n-butyl group, iso-butyl group, sec-butyl, t-butyl, n-pentyl group, n-hexyl group, n-heptyl group, n-octyl group, n-nonyl group, n-decyl, n-undecyl group and n-dodecyl group, and a cyclic alkyl group such as cyclopropyl group, cyclobutyl group, cyclopentyl group and cyclohexyl group. The alkyl group is preferably an alkyl group having a carbon number of 2 to 6, more preferably a linear or branched alkyl group having a carbon number of 2 to 6.

Examples of the alkenyl groups having a carbon number of 2 to 18 described as the organic group represented by R₁ of formula (1) include vinyl group, propenyl group, 1-butenyl group, iso-butenyl group, 1-pentenyl group, 2-pentenyl group, 2-methyl-1-butenyl group, 3-methyl-1-butenyl group, 2-methyl-2-butenyl group, 2,2-dicyanovinyl group, 2-cyano-2-methylcarboxyvinyl group and 2-cyano-2-methylsulfonevinyl group.

Examples of the alkynyl group having a carbon number of 2 to 18 described as the organic group represented by R₁ of formula (1) include ethynyl group, 1-propynyl group and 1-butynyl group.

Examples of the aryl groups having a carbon number of 6 to 12 described as the organic group represented by R₁ of formula (1) include phenyl group, naphthyl group and tolyl group. The aryl group is preferably an aryl group having a carbon number of 6 to 10.

Examples of the acyl groups having a carbon number of 1 to 18 described as the organic group represented by R₁ of formula (1) include formyl group, acetyl group, ethylcarbonyl group, n-propylcarbonyl group, iso-propylcarbonyl group, n-butylcarbonyl group, n-pentylcarbonyl group, iso-pentylcarbonyl group, neo-pentylcarbonyl group, 2-methylbutyl carbonyl group and nitrobenzylcarbonyl group.

Examples of the aroyl groups having a carbon number of 7 to 18 described as the organic group represented by R₁ of formula (1) include benzoyl group, toluoyl group, naphthoyl group and phthaloyl group.

Examples of the alkylthio group having a carbon number of 1 to 18 described as the organic group represented by R₁ of formula (1) include methylthio group, ethylthio group, n-propylthio group, iso-propylthio group, n-butylthio group, iso-butylthio group, sec-butylthio group, t-butylthio group, n-pentylthio group, iso-pentylthio group, 2-methylbutylthio group, 1-methylbutylthio group, neo-pentylthio group, 1,2-dimethylpropylthio group and 1,1-dimethylpropylthio group.

Examples of the halogen atom described of the organic group represented by R₁ of formula (1) include fluorine atom, chlorine atom, bromine atom and iodine atom.

R₁ in formula (1) is preferably a hydroxy group or an alkoxy group, more preferably a hydroxy group or an alkoxy group having a carbon number of 1 to 6, further preferably a hydroxy group or an alkoxy group having a carbon number of 1 to 4 and especially preferably a hydroxy group.

In formula (1), R₂, R₃, R₅ and R₆ each independently represent hydrogen atom, halogen atom, hydroxy group, alkoxy group, mercapto group, sulfide group, silyl group, silanol group, nitro group, nitroso group, cyano group, sulfino group, sulfo group, sulfonate group, phosphino group, phosphinyl group, phosphono group, phosphonato group, amino group, ammonio group or organic group other than the aforementioned groups. Each of R₂, R₃, R₅ and R₆ plurally existing may be the same or different from each other. R₂ and R₃ existing on the same benzene ring may be connected to form a ring structure, R₅ and R₆ existing on the same benzene ring may be connected to form a ring structure, and the ring structure may have a bond with a hetero atom.

Examples of the halogen atom represented by R₂, R₃, R₅ and R₆ of formula (1) are the same as the examples described in the halogen atoms represented by R₁ in formula (1).

Examples of the alkoxy group represented by R₂, R₃, R₅ and R₆ of formula (1) include are the same as the examples described in the alkoxy group represented by R₁ in formula (1).

Examples of the organic group represented by R₂, R₃, R₅ and R₆ of formula (1) include alkyl group, aryl group, aralkyl group, halogenated alkyl group, isocyano group, cyanate group, isocyanato group, thiocyanato group, isothiocyanato group, alkoxycarbonyl group, carbamoyl group, thiocarbamoyl group, carboxy group, carboxylate group, acyl group, acyloxy group, and hydroxyimino group.

Examples of the alkyl group, the aryl group and the acyl group as examples of the organic group represented by R₂, R₃, R₅ and R₆ of formula (1) are the same as the examples described in the alkyl group, the aryl group and the acyl group as examples of the organic group represented by R₁ in formula (1). Also the halogenated alkyl group is preferably a halogenated alkyl group having a carbon number of 1 to 20, the alkoxycarbonyl group is preferably an alkoxycarbonyl group having an alkoxy moiety having a carbon number of 1 to 18, and the acyloxy group is preferably an acyloxyl group having an acyl moiety having a carbon number of 1 to 20.

These organic groups may have a bond with a hetero atom except for a hydrocarbon in the organic group, and may have a substituent except for hydrocarbon group, which may be linear or branched. The organic group of R₂, R₃, R₅ and R₆ is usually a monovalent organic group, but, in the case where a cyclic structure is formed described below, the organic group may be a di- or more valent organic group.

A bond except for the bond of a hydrocarbon group which may be included in the organic group represented by R₂, R₃, R₅ and R₆ is not particularly limited as long as the advantageous effects of the present invention are not damaged. Examples of the bond except for the bond of the hydrocarbon include an ether bond, a thioether bond, a carbonyl bond, a thiocarbonyl bond, an ester bond, an amide bond, a urethane bond, a carbonate bond, a sulfonyl bond, a sulfinyl bond, and an azo bond. As a bond in the organic group except for the bond of the hydrocarbon group, an ether bond, a thioether bond, a carbonyl bond, a thiocarbonyl bond, an ester bond, an amide bond, a urethane bond, an imino bond (—N═C(—R)—, —C(═NR)— wherein R represents a hydrogen atom or an organic group), a carbonate bond, a sulfonyl bond or a sulfinyl bond are preferable, in view of the heat resistant.

A substituent except for a hydrocarbon group which may be connected to the organic group represented by R₂, R₃, R₅ and R₆ is not particularly limited as long as the advantageous effects are not damaged. Examples of the substituent except for the hydrocarbon group includes halogen atom, hydroxy group, mercapto group, sulfide group, cyano group, isocyano group, cyanate group, isocyanato group, thiocyanato group, isothiocyanato group, silyl group, silanol group, alkoxy group, alkoxycarbonyl group, carbamoyl group, thiocarbamoyl group, nitro group, nitroso group, carboxy group, carboxylate group, acyl group, acyloxy group, sulfino group, sulfo group, sulfonato group, phosphino group, phosphinyl group, phosphono group, phosphonato group, hydroxy imino group, saturated or unsaturated alkyl ether group, saturated or unsaturated alkylthio ether group, aryl ether group, arylthio ether group, amino group (—NH₂, —NHR, and —NRR′: wherein R and R′ are independently hydrocarbon group), and ammonio group. The hydrogen atom included in the above substituents may be replaced with a hydrocarbon group. The hydrocarbon group included in the substituents may be linear, branched or cyclic. Among them, the preferable substituents except for the hydrocarbon group in the organic group of R₂, R₃, R₅ and R₆ are halogen atom, hydroxy group, mercapto group, sulfide group, cyano group, isocyano group, cyanato group, isocyanato group, thiocyanato group, isothiocyanato group, silyl group, silanol group, alkoxy group, alkoxycarbonyl group, carbamoyl group, thiocarbamoyl group, nitro group, nitroso group, carboxy group, carboxylate group, acyl group, acyloxy group, sulfino group, sulfo group, sulfonato group, phosphino group, phosphinyl group, phosphono group, phosphonato group, hydroxyimino group, saturated or unsaturated alkyl ether group, saturated or unsaturated alkylthioether group, arylether group or arylthioether group.

R₂ and R₃ existing on the same benzene ring may be connected to form a cyclic structure, and R₅ and R₆ existing on the same benzene ring may be connected to form a cyclic structure. The cyclic structure may be a saturated or unsaturated alicyclic hydrocarbon, a heterocyclic structure, a condensed ring and a structure having the combination of two or more selected from the saturated or unsaturated alicyclic hydrocarbon, the heterocyclic ring and the condensed ring. For example, R₂ and R₃ are connected and/or R₅ and R₆ are connected to each other to share the atoms of the benzene ring connected to R₂, R₃, R₅ and R₆ so as to form a condensed ring such as a naphthalene, an anthracene, a phenanthrene and an indene.

The preferred examples of the organic group represented by R₂, R₃, R₅ and R₆ include alkyl group having a carbon number of 1 to 20 such as methyl group, ethyl group and propyl group; a cycloalkyl group having a carbon number of 4 to 23 such as cyclopentyl group and cyclohexyl group; cycloalkenyl group having a carbon number of 4 to 23 such as cyclopentenyl group and cyclohexenyl group; an aryloxy alkyl group (—ROAr group) having a carbon number of 7 to 26 such as phenoxymethyl group, 2-phenoxyethyl group and 4-phenoxybutyl group; aralkyl group having a carbon number of 7 to 20 such as benzyl group and 3-phenylpropyl group; alkyl group having a cyano group having a carbon number of 2 to 21 such as cyanomethyl group and β-cyanoethyl group; alkyl group having a hydroxy group having a carbon number of 1 to 20 such as hydroxymethyl group; alkoxy group having a carbon number of 1 to 20 such as methoxy group and ethoxy group; amido group having a carbon number of 2 to 21 such as acetamide group and benzenesulfonamide group (C₆H₅SO₂NH—); alkylthio group (—SR group) having a carbon number of 1 to 20 such as methylthio group and ethylthio group; acyl group having a carbon number of 1 to 20 such as acetyl group and benzoyl group; ester group (—COOR group and —OCOR group) having a carbon number of 2 to 21 such as methoxy carbonyl group and acetoxy group; aryl group having a carbon number of 6 to 20 such as phenyl group, naphthyl group, biphenyl group and tolyl group; aryl group having a carbon number of 6 to 20 where an electron-donating group and/or an electron-withdrawing group is/are substituted; benzyl group where an electron-donating group and/or an electron-withdrawing group is/are substituted; cyano group; and methylthio group (—SCH₃ group). The alkyl moiety of the substituents described above may be linear, branched or cyclic.

Also, when in the compound at least one of R₂, R₃, R₅ and R₆ is a hydroxy group, the solubility in a basic aqueous solution, etc., can be improved and also the absorption wavelength of the compound represented by formula (1) can be longer, compared with a case where none of R₂, R₃, R₅ and R₆ is a hydroxy group.

It is preferable that all R₂, R₃, R₅ and R₆ in formula (1) are hydrogen atoms.

In formula (1), R₄ each independently represents a hydrogen atom or an organic group having a thioether bond. At least one of R₄ is an organic group having a thioether bond. The organic group having a thioether bond represented by R₄ may be connected to R₃ or R₅ to form a ring structure.

Examples of the organic group mentioned in the above are the same as the examples described in the organic group represented by R₂, R₃, R₅ and R₆ in formula (1), but the organic group represented by R₄ is preferably alkyl group or aryl group. Therefore, R₄ in formula (1) is preferably alkylthio group or arylthio group, more preferably alkylthio group having a carbon number of 1 to 20. In this specification, as an example of the organic group having a thioether bond, the alkyl group (the aryl group) having a thioether bond include the embodiment “—S-Alkyl group (Aryl group)”. In this case, the sulfur atom of the thioether bond is directly connected to the benzene ring in the skeleton constituting formula (1).

The cyclic structure formed by connecting the organic group having a thioether bond represented by R₄ to R₃ or R₅ may be saturated or unsaturated alicyclic hydrocarbon, heterocyclic ring, condensed ring and a structure having the combination of two or more selected from the saturated or unsaturated alicyclic hydrocarbon, the heterocyclic ring and the condensed ring.

In formula (1), A represents the substituent group represented by formula (1-1) or formula (1-2).

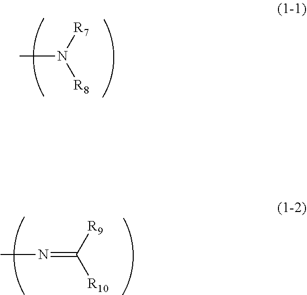

In formula (1-1), R₇ and R₈ each independently represent a hydrogen atom, an alkyl group, or a heterocyclic group or may be connected to form a heterocyclic ring.

Examples of the alkyl group represented by R₇ and R₈ of formula (1-1) are the same as the examples described in an alkyl group having a carbon number of 1 to 18 as an example of the organic group represented by R₁ in formula (1), and also the same as the examples described in the alkyl group as a substituent which the heterocyclic group represented by R₇ and R₈ of formula (1-1) described below has.

The alkyl group represented by R₇ and R₈ of formula (1-1) may have a substituent or not. The alkyl group represented by R₇ and R₈ include not only linear or branched alkyl group but also cyclic alkyl group (cycloalkyl group).

The substituent which may be connected to the alkyl group represented by R₇ and R₈ of formula (1-1) is not limited, and the examples include alkoxy group, aromatic group, heterocyclic group, halogen atom, hydroxy group, mercapto group, nitro group, alkyl-substituted amino group, aryl-substituted amino group, nonsubstituted amino group (NH₂ group), cyano group, and isocyano group. These specific examples are the same as the substituent which may be connected to the heterocyclic group represented by R₇ and R₈ of formula (1-1) described below. For example, the substituent is preferably 2-acryloyloxygruop or 2-methacryloyloxy group and is more preferably 2-methacryloyloxy group.

Examples of the heterocyclic group represented by R₇ and R₈ of formula (1-1) is not particularly limited as long as the heterocyclic group is a residue obtained by removing one hydrogen atom from the heterocyclic ring in the heterocyclic compound, and include furanyl group, thienyl group, thienothienyl group, pyrrolyl group, imidazolyl group, N-methylimidazolyl group, thiazolyl group, oxazolyl group, pyridyl group, pyradyl group, pylimidyl group, quinolyl group, indolyl group, benzopyradyl group, benzopylimidyl group, benzothienyl group, naphtothienyl group, benzofuranyl group, benzothiazoyl group, pyridinothiazoyl group, benzoimidazolyl group, pyridinoimidazolyl group, N-methylbenzoimidazolyl group, pyridino-N-methylimidazolyl group, benzooxazolyl group, pyridinooxazolyl group, benzothiadiazolyl group, pyridinothiadiazolyl group, benzooxadiazolyl group, pyridinooxadiazolyl group, carbazolyl group, phenoxazinyl group, and phenothiazinyl group. The heterocyclic group is preferably pyridyl group, imidazolyl group, and N-methylimidazolyl group, more preferably pyridyl group.

The heterocyclic group represented by R₇ and R₈ of formula (1-1) may have a substituent. The substituent connected to the heterocyclic group represented by R₇ and R₈ of formula (1-1) is not limited, but examples include alkyl group, alkoxyl group, aromatic group, heterocyclic group, halogen atom, hydroxy group, mercapto group, nitro group, alkyl-substituted amino group, aryl-substituted amino group, nonsubstituted amino group (NH₂ group), cyano group, and isocyano group. The substituent is more preferably alkyl group, aromatic group, heterocyclic group or halogen atom, and is especially preferably alkyl group, aromatic group or heterocyclic group.

Examples of the alkyl group as the substituent which may be connected to the heterocyclic group represented by R₇ and R₈ of formula (1-1) are preferably an alkyl group having a carbon number of 1 to 20 such as methyl group, ethyl group, propyl group, iso-propyl group, n-butyl group, iso-butyl group, t-butyl group, n-pentyl group, iso-pentyl group, t-pentyl group, sec-pentyl group, n-hexyl group, iso-hexyl group, n-heptyl group, sec-heptyl group, n-octyl group, n-nonyl group, sec-nonyl group, n-decyl group, n-undecyl group, n-dodecyl group, n-tridecyl group, n-tetradecyl group, n-pentadecyl group, n-hexadecyl group, n-heptadecyl group, n-octadecyl group, n-nonadecyl group, and n-eicosyl group, more preferably an alkyl group having a carbon number of 1 to 12, further preferably an alkyl group having a carbon number of 1 to 6, especially preferably an alkyl group having a carbon number of 1 to 4.

The alkoxy group as the substituent which may be connected to the heterocyclic group represented by R₇ and R₈ of formula (1-1) is a substituent obtained by bonding an oxygen atom with an alkyl group. Examples of the alkyl group in the alkoxy group are the same as the examples described in the alkyl group as a substituent which may be connected to the heterocyclic group represented by R₇ and R₈ of formula (1-1). The preferable examples of the alkyl group in the alkoxy group also are the same as the preferable examples described there.

The aromatic group as a substituent which may be connected to the heterocyclic group represented by R₇ and R₈ of formula (1-1) is not limited as long as the aromatic group is a residue obtained by removing one hydrogen atom from the aromatic ring in aromatic compound. Examples include phenyl group, biphenyl group, terphenyl group, quarterphenyl group, tolyl group, indenyl group, naphthyl group, anthryl group, fluorenyl group, pyrenyl group, phenanthryl group and mesityl group. Phenyl group, biphenyl group, terphenyl group, quarterphenyl group, naphthyl group, and anthryl group are preferable. Phenyl group, biphenyl group, terphenyl group, and naphthyl group are more preferable.

Examples of the heterocyclic group as a substituent which may be connected to the heterocyclic group represented by R₇ and R₈ of formula (1-1) are the same as examples of described in the heterocyclic group represented by R₇ and R₈ of formula (1-1). The preferable examples of the heterocyclic group also are the same as the preferable examples described there.

Examples of the halogen atom as a substituent which may be connected to the heterocyclic group represented by R₇ and R₈ of formula (1-1) include fluorine atom, chlorine atom, bromine atom, and iodine atom. Fluorine atom and chlorine atom are preferable. Fluorine atom is more preferable.

The alkyl-substituted amino group as a substituent which may be connected to the heterocyclic group represented by R₇ and R₈ of formula (1-1) is limited to neither monoalkyl-substituted amino group nor dialkyl-substituted amino group. Examples of the alkyl group in alkyl-substituted amino group are the same as the examples described in the alkyl group as the substituent which may be connected to the heterocyclic group represented by R₇ and R₈ of formula (1-1). The preferable examples of the alkyl group also are the same as the preferable examples described there.

The aryl-substituted amino group as a substituent which may be connected to the heterocyclic group represented by R₇ and R₈ of formula (1-1) is limited to neither monoaryl-substituted amino group nor diaryl-substituted amino group. Examples of the aryl group in aryl-substituted amino group are the same as the examples described in the aromatic group as the substituent which may be connected to the heterocyclic group represented by R₇ and R₈ of formula (1-1) and also the same as the examples described in the heterocyclic group represented by R₇ and R₈. The preferable examples of the aryl group also are the same as the preferable examples described there.

The heterocyclic ring formed by connecting R₇ with R₈ of formula (1-1) is not limited as long as the heterocyclic ring has a ring structure having two or more elements. Examples include thiophene ring, furan ring, pyrrole ring, pyridine ring, imidazole ring, pyrazole ring, oxazole ring, thiazole ring, pyrazine ring, and thiazine ring. Pyridine ring, and imidazole ring are preferable. Pyridine ring is more preferable.

The heterocyclic ring formed by connecting R₇ with R₈ of formula (1-1) may have one or more substituents.

The substituent which may be connected to the heterocyclic ring formed by connecting R₇ and R₈ of formula (1-1) is not limited. Examples are the same as the examples described in the substituent which may be connected to the heterocyclic group represented by R₇ and R₈ of formula (1-1).

R₇ and R₈ of formula (1-1) are preferably each independently a hydrogen atom or an alkyl group having a carbon number of 1 to 18, and it is more preferable that one of R₇ and R₈ is hydrogen atom and the other is an alkyl group having a carbon number of 1 to 18. Note that for example, the compound represented by formula (2) or (3) described below is involved in the aforementioned compound where one of R₇ and R₈ is a hydrogen atom and the other is an alkyl group having a carbon number of 1 to 18.

For example, the compound represented by formula (2) described below falls into the scope of the compound represented by formula (1) in which A is represented by formula (1-1).

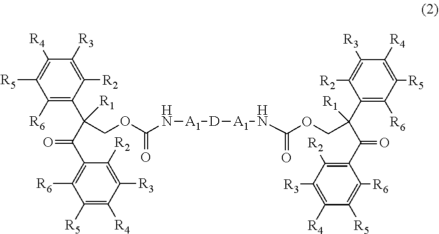

In formula (2) the meanings of R₁ to R₆ are the same as those of R₁ to R₆ of formula (1) and the preferable R₁ to R₆ are the same as preferable R₁ to R₆ of formula (1). A₁ represents a cycloalkylene group. D represent an alkylene group.

The cycloalkylene group represented by A₁ of formula (2) is a bivalent connecting group obtained by removing two hydrogen atoms from a saturated cyclic hydrocarbon such as cyclopropane ring, cyclobutane ring, cyclopentane ring, cyclohexane ring, and adamantane ring. Preferable is 1,3-cyclopentylene group or 1,4-cyclohexylene group. More preferable is 1,4-cyclohexylene group. The alkylene group represented by D of formula (2) is a bivalent connecting group obtained by removing two hydrogen atoms from a saturated aliphatic hydrocarbon (for example, methane, ethane, propane, butane, pentane, hexane, heptane, and octane). The alkylene group having a carbon number of 1 to 18 is preferable. The alkylene group having a carbon number of 1 to 12 is more preferable. The linear alkylene group having a carbon number of 1 to 8 (specifically methylene group, ethylene group, propylene group, butylene group, pentylene group, hexylene group, heptylene group, and octylene group) is further preferable. The alkylene group having a carbon number of 1 to 4 is especially preferable. The alkylene group having a carbon number of 1 (namely methylene group) is the most preferable.

Namely, the compound represented by formula (3) described below is more preferable for the compound represented by formula (2).

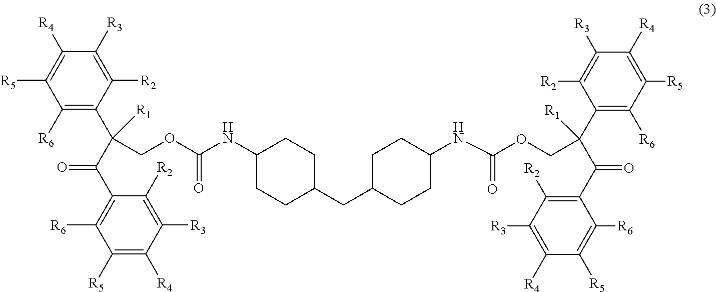

In formula (3), R₁ to R₆ have the same meanings as R₁ to R₆ in formula (2) and the preferable examples of R₁ to R₆ in formula (3) are the same as the preferable examples of R₁ to R₆ in formula (2).

R₉ and R₁₀ of formula (1-2) each independently represent an amino group or a substituted amino group. Specific examples of the amino group represented by R₉ and R₁₀ of formula (1-2) are the same as the examples described in the alkyl-substituted amino group and also the same as the examples of the aryl-substituted amino group as a substituent which may be connected to the heterocyclic group represented by R₇ and R₈ of formula (1-1).

R₉ and R₁₀ of formula (1-2) are preferably each independently alkyl-substituted amino group or aryl-substituted amino group, more preferably alkyl-substituted amino group.

As the substituent A of formula (1), the substituent represented by formula (1-1) is more preferable.

Also, as the compound represented by formula (1), the compound obtained by combining preferable R₁ to R₆ and preferable A (R₇ to R₁₀ of formula (1-1) or (1-2) in A) described above is more preferable.

The compound represented by formula (1) of the present invention generates a radical and a base with the cleavage reaction and the decarboxylation reaction by the irradiation of active energy ray as shown in the reactions described below to start the radical polymerization of the resin composition.

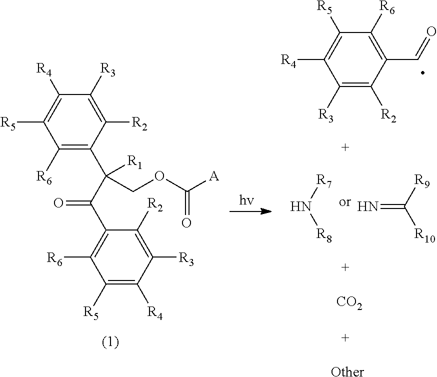

Next, the synthetic method of the compound represented by formula (1) will be explained.

The compound represented by formula (1) can be synthesized by using a well-known method. For example, a paraformaldehyde is reacted with a benzoin derivative represented by formula (21) in the presence of a metal hydroxide at a room temperature for 30 minutes to produce an intermediate compound represented by formula (22-1). After that, the intermediate compound (22-1) is reacted with sodium nitrite in the presence of sulfuric acid, etc., to produce the intermediate compound represented by formula (23). Next, the intermediate compound represented by formula (23) obtained above is reacted with carbon monoxide and chlorine under a catalyst to produce an intermediate compound represented by formula (24). Lastly the intermediate compound represented by formula (24) is reacted with an amine compound to produce the compound represented by formula (1). As a purified method, a crystallization method is suitable because the compound obtained by the crystallization method has high crystallinity. Alternatively, purification may be conducted by washing using a solvent. Note that the meanings of R₁ to R₆ and A in formulas (21) to (24) and in the amine compound AH are the same as those of R₁ to R₆ and A in formula (1).

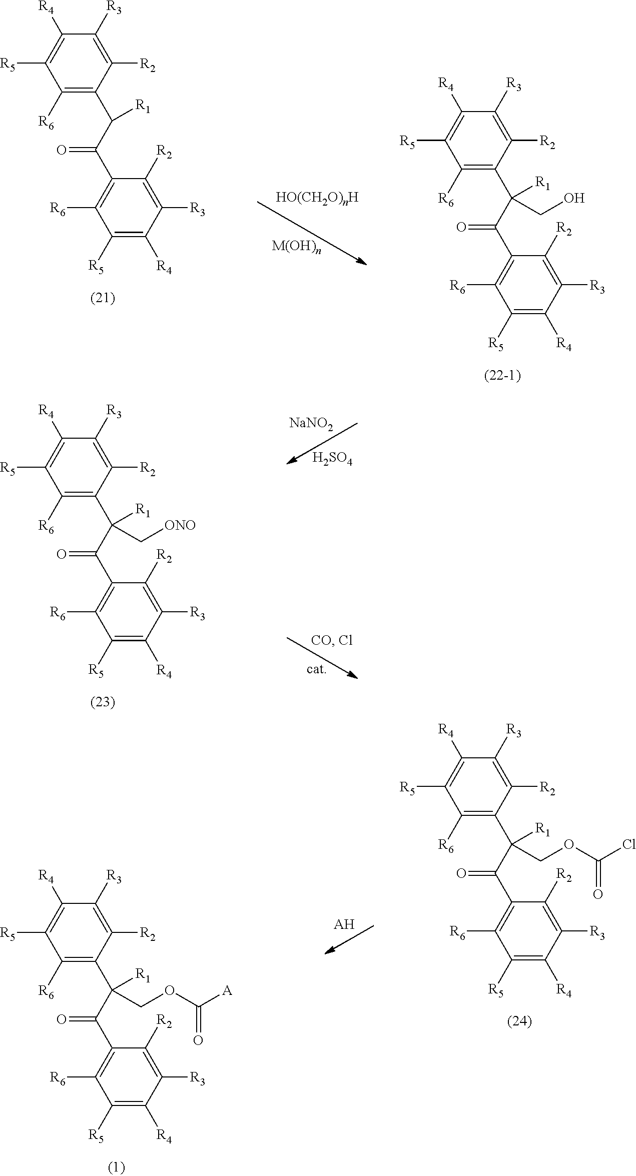

When A in formula (1) is the substituent represented by formula (1-1), by using a method disclosed in J. Photopolym. Sci. Technol 27, 2, 2014, for example, a paraformaldehyde is reacted with a benzoin derivative represented by formula (21) in the presence of a metal hydroxide at a room temperature for 30 minutes to produce an intermediate compound of formula (22-2). After that, the intermediate compound (22-2) is reacted with an isocyanate in the presence of a catalyst of an organic compound including tin or lead, etc., so as to obtain the compound represented by formula (1). The purified method is the same ones described above. Note that the meanings of R₁ to R₈ in formulas (21) to (22-2) and an isocyanate are the same as those of R₁ to R₈ in formula (1).

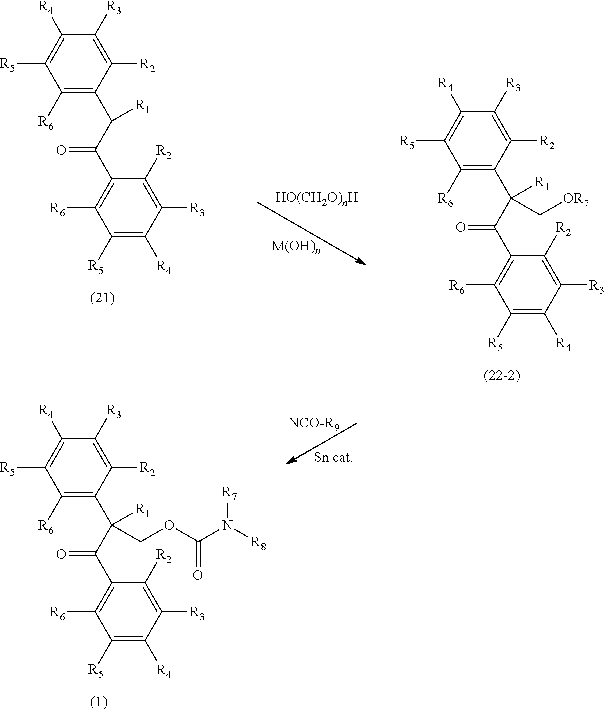

Specifically, examples of the compound represented by formula (1) are shown as formulas (a) to (g) described below, but the compound represented by formula (1) is not limited to these compounds.

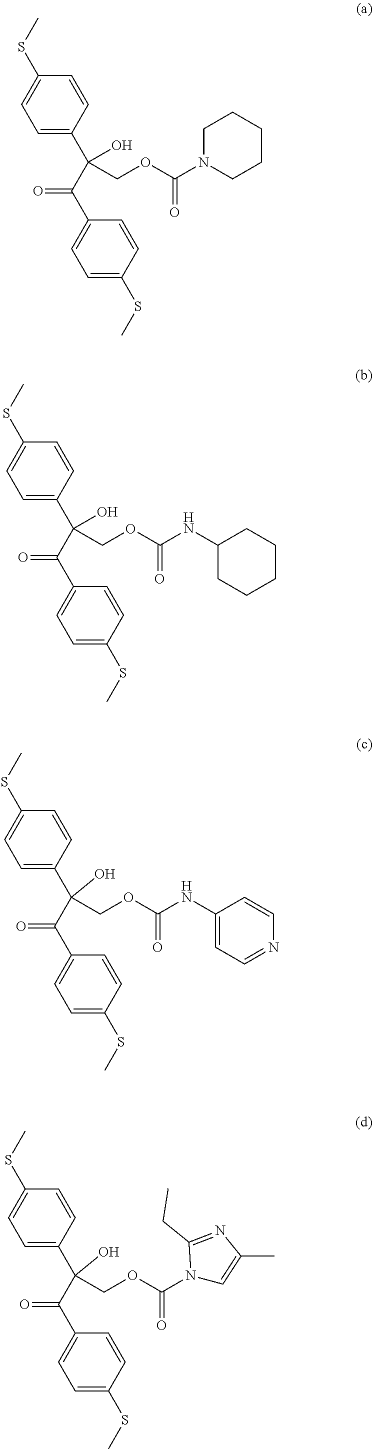 [SMILES: CSc1ccc(C(=O)C(O)(COC(=O)N2CCCCC2)c2ccc(SC)cc2)cc1 ; CSc1ccc(C(=O)C(O)(COC(=O)NC2CCCCC2)c2ccc(SC)cc2)cc1 ; CSc1ccc(C(=O)C(O)(COC(=O)Nc2ccncc2)c2ccc(SC)cc2)cc1 ; CCc1nc(C)cn1C(=O)OCC(O)(C(=O)c1ccc(SC)cc1)c1ccc(SC)cc1]

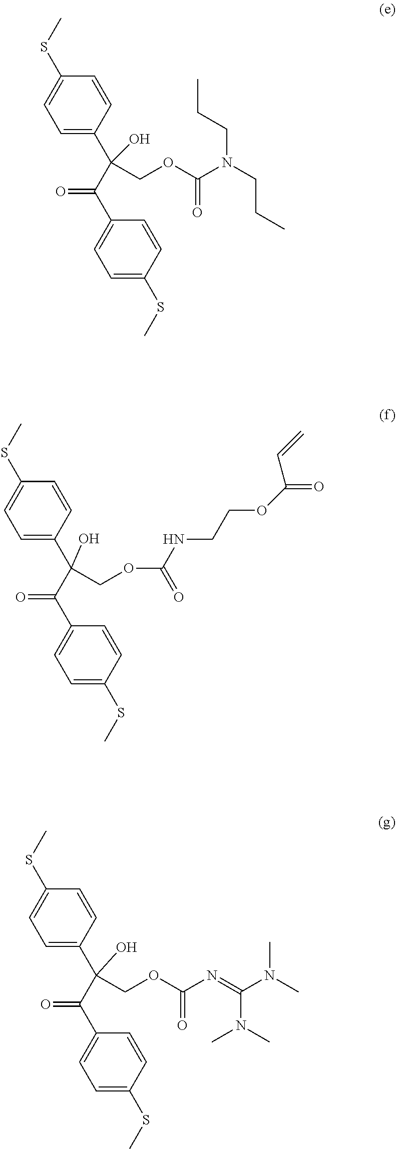 [SMILES: CCCN(CCC)C(=O)OCC(O)(C(=O)c1ccc(SC)cc1)c1ccc(SC)cc1 ; C=CC(=O)OCCNC(=O)OCC(O)(C(=O)c1ccc(SC)cc1)c1ccc(SC)cc1 ; CSc1ccc(C(=O)C(O)(COC(=O)N=C(N(C)C)N(C)C)c2ccc(SC)cc2)cc1]

The photobase generator containing the compound represented by formula (1) needs to have the absorption in at least part of the exposure wavelength to produce a radical and a base which can contribute sufficiently to the polymerization reaction or the condensed polymerization reaction of the resin composition. Because the wavelength of the high-pressure mercury vapor lamp which is a general exposure light source is 365 nm, 405 nm and 436 nm, the compound preferably has the absorption of the activity energy ray having at least one of these wavelengths.

The molar absorbance coefficient of the photobase generator containing the compound represented by formula (1) is preferably 100 or more to the active energy ray having a wavelength of 365 nm, or 1 or more to the active energy ray having a wavelength of 405 nm.

The absorbance at the wavelength region described above which the compound represented by formula (1) has can be confirmed by solving the compound in a solvent (e.g., acetonitrile) having no absorbance in the wavelength region to make a solution having a concentration of not more than 1×10⁻⁴ mol/L (usually about from 1×10⁻⁵ mol/L to 1×10⁻⁴ mol/L) of the compound represented by formula (1) and measuring the absorbance of the solution by a ultraviolet and visible spectrophotometer (for example, UV-2550 manufactured by Shimazu Corporation).

The content of the photobase generator containing the compound represented by formula (1) in the resin composition of the present invention is usually 0.1 to 95% by mass to the total solid content of (B) the alkali developable resin and (C) the thermal reactive compound, and preferably 0.5 to 60% by mass. When the content of the photobase generator is less than 0.1% by mass, the contrast of solubility between exposed areas and unexposed areas may not become large sufficiently. When the content of the photobase generator exceeds 95% by mass, it may be difficult for the cured product of the resin composition to exhibit the several characteristics.

### <(B) Alkali Developable Resin>

The resin composition of the present invention contains (B) the alkali developable resin.

The alkali developable resin may contain one or more of functional groups selected from phenolic hydroxy group, thiol group, and carboxy group and is a resin which is developable by alkali solution (The resin is soluble in alkali solution). The preferable examples of the alkali developable resin include the compound having two or more phenolic hydroxy groups, the resin having a carboxy group, the compound having a phenolic hydroxy group and a carboxy group, and the compound having two or more thiol groups.

Examples of the compound having two or more phenolic hydroxy groups include the well-known conventional phenol resin such as phenol novolac resin, alkyl phenol novolac resin, bisphenol A novolac resin, dicyclopentadiene type phenol resin, Xyiok type phenol resin, terpene-modified phenol resin, polyvinylphenol, bisphenol F, bisphenol S type phenol resin, poly-p-hydroxystyrene, condensate of naphthol and aldehyde, and condensate of dihydroxynaphthalene and aldehyde.

Also, as a phenol resin, the phenol resin having one or more of various skeletons synthesized by using the compound having biphenyl skeleton, phenylene skeleton or both the skeletons and the compound having phenolic hydroxy group such as phenol, orthocresol, paracresol, metacresol, 2,3-xylenol, 2,4-xylenol, 2,5-xylenol, 2,6-xylenol, 3,4-xylenol, 3,5-xylenol, catechol, resorcinol, hydroquinone, methylhydroquinone, 2,6-dimethylhydroquinone, trimethylhydroquinone, pyrogallol, and phloroglucinol may be used.

These phenol resins may be used alone or in combination of two or more

As a resin having a carboxy group, the well-known conventional resin having a carboxy group can be used. The presence of carboxy group allows the resin composition to be alkali developable. Also, the compound having an ethylenically unsaturated bond in addition to a carboxy group may be used, but in the present invention only the resin having a carboxy group and no ethylenically unsaturated bond is preferably used.

The specific examples of the resin having a carboxy group which is usable in the present invention include the compound (either of oligomer and polymer may be used) listed in items (1) to (19) as follows.

Item (1): The resin having a carboxy group obtained by copolymerizing an unsaturated carboxylic acid such as (meth)acrylic acid and a compound having unsaturated group such as styrene, α-methylstyrene, lower alkyl (meth)acrylate and isobutylene. Note that the lower alkyl means the alkyl group having a carbon number of 1 to 5.

Item (2): The urethane resin having a carboxy group obtained by polyaddition reaction of a diisocyanate such as aliphatic diisocyanate, branched aliphatic diisocyanate, alicyclic diisocyanate, aromatic diisocyanate; a dialcohol compound having a carboxy group such as dimethylol propionic acid and dimethylol butanoic acid; and a diol compound such as polycarbonate polyol, polyether polyol, polyester polyol, polyolefin polyol, acryl polyol, bisphenol A alkylene oxide adduct diol and the compound having a phenolic hydroxy group and an alcoholic hydroxy group.

Item (3): The urethane resin having a terminal carboxy group obtained by reacting an acid anhydride with the terminal of the urethane resin obtained by polyaddition reaction of a diisocyanate such as aliphatic diisocyanate, branched aliphatic diisocyanate, alicyclic diisocyanate, aromatic diisocyanate; a dialcohol compound having a carboxy group such as dimethylol propionic acid and dimethylol butanoic acid; and a diol compound such as polycarbonate polyol, polyether polyol, polyester polyol, polyolefin polyol, acryl polyol, bisphenol A alkylene oxide adduct diol and the compound having a phenolic hydroxy group and an alcoholic hydroxy group.

Item (4): The urethane resin having a carboxy group obtained by polyaddition reaction of a diisocyanate; a (meth)acrylate or a partially acid anhydride modified resin of a difunctional epoxy resin such as bisphenol A type epoxy resin, hydrogenation bisphenol A type epoxy resin, bisphenol F type epoxy resin, bisphenol S type epoxy resin, bixylenol type epoxy resin and biphenol type epoxy resin; a dialcohol compound having a carboxy group; and a diol compound.

Item (5): The terminal (meth)acrylic urethane resin having a carboxy group obtained by adding a compound having one hydroxy group and one or more (meth)acryloyl group in the molecule such as hydroxyalkyl(meth)acrylate during the synthesis of the resin described above in Item (2) or (4).

Item (6): The terminal (meth)acrylic urethane resin having carboxy group obtained by adding a compound having one isocyanate group and one or more (meth)acryloyl group in the molecule such as the compound obtained by reacting isophorone diisocyanate and pentaerythritol triacrylate in equimolar amount during the synthesis of the resin described above in Item (2) or (4).

Item (7): The resin having a carboxy group obtained by reacting the multifunctional (solid) epoxy resin aforementioned with a unsaturated mono carboxylic acid such as (meth)acrylic acid; and adding a dibasic acid anhydride such as phthalic anhydride, tetrahydrophtalic anhydride and hexahydrophtalic anhydride to the hydroxy group in the side chain.

Item (8): The resin having a carboxy group obtained by reacting the multifunctional (solid) epoxy resin aforementioned with a saturated mono carboxylic acid and adding a dibasic acid anhydride such as phthalic anhydride, tetrahydrophtalic anhydride and hexahydrophtalic anhydride to the hydroxy group in the side chain.

Item (9): The resin having a carboxy group obtained by epoxidizing the hydroxy group of a difunctional (solid) epoxy resin with an epichlorohydrin to produce the multifunctional (solid) epoxy resin; then reacting the resultant multifunctional (solid) epoxy resin with (meth)acrylic acid; and further adding a dibasic acid anhydride to the hydroxy group generated by the reaction.

Item (10): The polyester resin having a carboxy group obtained by reacting a multifunctional oxetane resin described below with a dicarboxylic acid and further adding a dibasic acid anhydride to the primary hydroxy group generated by the reaction.

Item (11): The resin having a carboxy group obtained by reacting a compound having more than one phenolic hydroxy groups in one molecule with alkylene oxide such as ethylene oxide, propylene oxide; and further reacting the resultant reaction product with a multibasic acid anhydride.

Item (12): The resin having a carboxy group obtained by reacting the compound having more than one phenolic hydroxy groups in one molecule with alkylene oxide such as ethylene oxide, propylene oxide; then reacting the resultant reaction product with a saturated monocarboxylic acid; and further reacting the obtained reaction product with a multibasic acid anhydride.

Item (13): The resin having a carboxy group obtained by reacting a compound having more than one phenolic hydroxy groups in one molecule with an alkylene oxide such as ethylene oxide, propylene oxide; then reacting the resultant reaction product with monocarboxylic acid having a unsaturated group; and further reacting the obtained reaction product with a multibasic acid anhydride.

Item (14): The resin having a carboxy group obtained by reacting a compound having more than one phenolic hydroxy groups in one molecule with a cyclic carbonate compound such as ethylene carbonate and propylene carbonate; then reacting the resultant reaction product with a saturated monocarboxylic acid; and further reacting the obtained reaction product with a multibasic acid anhydride.

Item (15): The resin having a carboxy group obtained by reacting a compound having more than one phenolic hydroxy groups in one molecule with a cyclic carbonate compound such as ethylene carbonate and propylene carbonate; and then reacting the resultant reaction product with a multibasic acid anhydride.

Item (16): The resin having a carboxy group obtained by reacting a compound having more than one phenolic hydroxy groups in one molecule with a cyclic carbonate compound such as ethylene carbonate and propylene carbonate; then reacting the resultant reaction product with a mono carboxylic acid having a unsaturated group; and further reacting the obtained reaction product with a multibasic acid anhydride.

Item (17): The resin having a carboxy group obtained by reacting an epoxy compound having more than one epoxy groups in one molecule with a compound having at least one alcoholic hydroxy group and at least one phenolic hydroxy group in one molecule such as p-hydroxy phenethyl alcohol; then reacting the alcoholic hydroxy group of the resultant reaction product with a multibasic acid anhydride such as maleic anhydride, tetrahydro phthalic anhydride, trimellitic anhydride, pyromellitic anhydride and adipic acid.

Item (18): The resin having a carboxy group obtained by reacting an epoxy compound having more than one epoxy groups in one molecule with a compound having at least one alcoholic hydroxy group and at least one phenolic hydroxy group in one molecule such as p-hydroxy phenethyl alcohol and a mono carboxylic acid having unsaturated group such as (meth)acrylic acid; then reacting the alcoholic hydroxy group of the reaction product with a multibasic acid anhydride such as maleic anhydride, tetrahydro phthalic anhydride, trimellitic anhydride, pyromellitic anhydride and adipic acid.

Item (19): The resin having a carboxy group obtained by further adding a compound having one epoxy group and one or more (meth)acryloyl groups in the molecule such as glycidyl (meth)acrylate, α-methylglycidyl (meth)acrylate to any one of the resins according to Items (1) to (18) aforementioned.

Because (B) the alkali developable resin described above have more than one carboxy group or hydroxy group, etc. in side chain of backbone polymer, the resin composition may be developed with the alkali aqueous solution.

The hydroxy group equivalent or the carboxy group equivalent of (B) the alkali developable resin described above is preferably 80 to 900 g/eq., and more preferably 100 to 700 g/eq. When the hydroxy group equivalent or the carboxy group equivalent exceeds 900 g/eq., the adhesion of the pattern layer may not be obtained or alkali development may be difficult. While when the hydroxy group equivalent or the carboxy group equivalent is less than 80 g/eq., the dissolution of the light irradiated area by the developer may progress. Therefore, the line become thinner than necessary, in some cases the dissolution and stripping may occur by the developer without distinction between the light irradiated area and the unirradiated area, so the normal drawing of resist pattern may be difficult, which is not preferable. When the hydroxy group equivalent or the carboxy group equivalent is great, even when the content of the alkali developable resin is low, development be possible, which is preferable.

The weight-average molecular weight of (B) the alkali developable resin used for the present invention differs depending on the resin skeleton, but is preferably in the range of 2,000 to 150,000 and is more preferably in the range of 5,000 to 100,000. When the weight-average molecular weight is less than 2,000, tack free performance may be inferior, the moisture resistance of the resin layer after irradiation may be poor, the film reduction may occur during developing, and the resolution may be inferior highly. While when the weight-average molecular weight exceeds 150,000, developing performance may be poor remarkably, and storage stability may be inferior.

Note that the weight-average molecular weight in this specification means the value calculated in terms of polystyrene based on the measurement result of the gel permeation chromatography.

In this specification (meth)acrylate is the generic term for acrylate, methacrylate, and mixture of those, and the same may be applied to other similar expression.

Examples of the compound having a thiol group include trimethylol propane tris thiopropionate, pentaerythritol tetrakis thiopropionate, ethylene glycol bis thioglycolate, 1,4-butane diol bis thioglycolate, trimethylol propane tris thioglycolate, pentaerythritol tetrakis thioglycolate, di(2-mercaptoethyl) ether, 1,4-butanedithiol, 1,3,5-trimercaptomethylbenzene, 1,3,5-trimercaptomethyl-2,4,6-trimethylbenzene, polyether having terminal thiol group, polythioether having a terminal thiol group, the thiol compound obtained by the reaction of epoxy compound and hydrogen sulfide, and the thiol compound having a terminal thiol group obtained by the reaction of polythiol compound with an epoxy compound.

As (B) the alkali developable resin, a non-photosensitive resin having no photosetting structure such as epoxyacrylate is preferable. Because such non-photosetting alkali developable resin has no ester bond derived from epoxyacrylate, the resin has high resistance to desmear solution. Therefore, the pattern layer excellent in curing characteristics can be formed. Because (B) the alkali developable resin has no photosetting structure, cure shrinkage can be suppressed.

When (B) the alkali developable resin is the resin having carboxy group, the resin can be developed with weak alkaline solution compared to the phenolic resin. Examples of the weak alkaline solution includes the solution dissolving sodium carbonate etc. Developing with weak alkaline solution can suppress development of the irradiated area. The irradiation time in the step (b) described below and the heating time in the step (b1) can be shorten.

As (B) the alkali developable resin contained in the resin composition of the present invention, the resin having a carboxy group described above in item (7) is especially preferable.

For (B) the alkali developable resin, commercial products can be used. For example, ZCR-1569Z, ZAR-2001H, etc., can be used.

### <(C) Thermally Reactive Compound>

The resin composition of the present invention contains (C) the thermally reactive compound. (C) The thermally reactive compound is the resin or the compound having a functional group capable of curing reaction with heating. Examples include an epoxy resin and a multifunctional oxetane compound.

The epoxy resin is a resin having an epoxy group and any conventional epoxy resins can be used. Examples of the epoxy resin includes difunctional epoxy resin having two epoxy groups in the molecule and a multifunctional epoxy resin having two or more epoxy groups in the molecule. Moreover, the epoxy resin may be a difunctional epoxy compound hydrogenated.

Examples of the multifunctional epoxy resin include bisphenol A type epoxy resin, brominated epoxy resin, novolak type epoxy resin, bisphenol F type epoxy resin, hydrogenated bisphenol A type epoxy resin, glycidylamine type epoxy resin, hydantoin type epoxy resin, alicyclic epoxy resin, trihydroxyphenylmethane type epoxy resin, bixylenol type or biphenol type epoxy resin or the mixture of those, bisphenol S type epoxy resin, bisphenol A novolak type epoxy resin, tetraphenylolethane type epoxy resin, heterocyclic epoxy resin, diglycidylphtalate resin, tetraglycidylxylenolethane resin, the epoxy resin having naphthalene group, the epoxy resin having dicyclopentadiene skeleton, glycidylmethacrylate copolymer epoxy resin, the copolymer epoxy resin of cyclohexylmaleimide and glycidylmethacrylate, and CTBN-modified epoxy resin.

Examples of the other liquid difunctional epoxy resin include an alicyclic epoxy resin such as vinylcyclohexenediepoxide, (3′,4′-epoxycyclohexylmethyl)-3, 4-epoxycyclohexanecarboxylate, (3′, 4′-epoxy-6′-methylcyclohexylmethyl)-3,4-epoxy-6-methylcyclohexanecarboxylate. The epoxy resin having a naphthalene group is preferable, because the thermoexpanding of the cured product can be suppressed.

The epoxy equivalent of the epoxy resin is preferably 200 or more. When the epoxy equivalent is 200 or more, the warp of the cured film is suppressed, and the developability is excellent even when the epoxy resin is left under high humidity for a long time. Note that the epoxy equivalent in the present invention is a value measured by the method according to JIS K7236 and the molecular weight is a value of weight-average molecular weight calculated in terms of polystyrene based on the measurement results of the gel permeation chromatography

Examples of the epoxy resin having an epoxy equivalent of 200 or more include HP-4770 (naphthalene type, 205 g/eq.), HP-7200 (novolac epoxy having dicyclopentadiene skeleton, 255 g/eq.) EXA-4850-150 (liquid epoxy having flexible skeleton, 440 g/eq.) EXA-4850-1000 (340 g/eq.) and HP-820 (alkylphenolepoxy, 225 g/eq.) manufactured by DIC Corporation; PG-100 (epoxy having fluorene skeleton, 250 g/eq.), and EG-200 (flexible epoxy, 292 g/eq.) manufactured by Osaka Gas Chemical Co., Ltd.; 1001 (475 g/eq.), 1002 (650 g/eq.), 4004P (900 g/eq.), 4005P (1075 g/eq.), and 157S70 (Bis-A novolac epoxy, 210 g/eq.) manufactured by Mitsubishi Chemical Corporation; ENS-475V (naphtholaralkyl type, 325 g/eq.), YD-134 (bisphenol A type epoxy, 247 g/eq.) manufactured by NIPPON STEEL Chemical & Material Co., Ltd.; ECON-104S (cresol novolac epoxy, 210 g/eq.), NC-7000 (novolac epoxy having naphthalene skeleton, 230 g/eq.), NC-3000 (biphenylaralkyl type epoxy resin, 275 g/eq.), NC-3000H (phenolaralkyl type epoxy resin, 289 g/eq.), NC-3000-FH (phenolbiphenylaralkyl type epoxy resin, 320 g/eq.), NC-2000L (238 g/eq.), NC-3100 (258 g/eq.), NC-3000S (284 g/eq.), NC-3000S-H (290 g/eq.) manufactured by Nippon Kayaku Co., Ltd.

The epoxy resin described above may be used alone or together with one or more.

Examples of the multifunctional oxetane compound described above include a multifunctional oxetane such as bis[(3-methyl-3-oxetanylmethoxy)methyl]ether, bis[(3-ethyl-3-oxetanylmethoxy)methyl]ether, 1,4-bis[(3-methyl-3-oxetanylmethoxy)methyl]benzene, 1,4-bis[(3-ethyl-3-oxetanylmethoxy)methyl]benzene, (3-methyl-3-oxetanyl)methylacrylate, (3-ethyl-3-oxetanyl)methylacrylate, (3-methyl-3-oxetanyl)methylmethacrylate, (3-ethyl-3-oxetanyl)methylmethacrylate, and the oligomer or copolymer thereof, in addition, the compound obtained by etherifing an oxethane alcohol with a resin having a hydroxy group such as novolac resin, poly (p-hydroxystyrene), cardo type bisphenol, calixarene, calixresorcinarene, or silsesquioxane. Furthermore, a copolymer of the unsaturated monomer having an oxetane ring and an alkyl(meth)acrylate, etc. is also included.

When (C) the thermally reactive compound has a benzene skeleton, heat resistance is improved, which is preferable. When the resin composition contains white pigment, thermally reactive compound preferably has an alicyclic skeleton. Thereby, the photo reactivity can be improved.

In regard to the formulation ratio of (C) the thermally reactive compound, the equivalent ratio to (B) the alkali developable resin (the equivalent of thermally reactive group (epoxy group, oxetane moiety etc.): the equivalent of alkali developable group (phenolic hydroxy group, carboxy group etc.)) is preferably 1:0.1 to 1:10, and is more preferably 1:0.2 to 1:5. When the formulation ratio falls into the range, the development is excellent.

As (C) the thermally reactive compound contained in the resin composition of the present invention is preferably an epoxy resin.

### <Other Components>

In the resin composition of the present invention, other photobase generator except for (A) the photobase generator containing the compound represented by formula (1) may be used together. The other photobase generator is a compound capable of producing one or more base materials which may work as a catalyst for additional reaction of (meth)acrylate having an epoxy group with a thermal curing component by change of molecule structure or by the cleavage of molecule by irradiation of rays such as ultraviolet rays or visible light. Examples of the base material generated include a secondary amine and a tertiary amine.

Examples of the photobase generator which can be used together include an α-amino acetophenone compound, an oxime ester compound, and a compound having one or more substituents such as an acyl oxyimino group, a N-formulation aromatic amino group, a N-acylation aromatic amino group, a nitro benzyl carbamate group or an alkoxybenzyl carbamate group. Among them, an oxime ester compound and an α-amino acetophenone compound are preferable. As an α-amino acetophenone compound, the compound having two or more nitrogen atoms is particularly preferable. As other photobase generators, WPBG-018 (product name; 9-anthrylmethyl N, N′-diethylcarbamate, manufacture by Wako Pure Chemical Industries Ltd.), WPBG-027 (product name; (E)-1-[3-(2-hydroxyphenyl)-2-propenoyl]piperidine), WPBG-082 (product name: guanidinium 2-(3-benzoylphenyl)propionate), WPBG-140 (product name; 1-(anthraquinon-2-yl)ethylimidazolecarboxylate), etc., can also be used. An α-amino acetophenone compound has a benzoin ether bond in the molecule, which provides cleavage in the molecule by irradiation to produce a base material (amine), which works as a curing catalyst. Specifically, examples of the α-amino acetophenone include commercial compounds or solutions thereof such as (4-morpholinobenzoyl)-1-benzyl-1-dimethylamino propane (Irgacure 369, product name, manufactured by BASF Japan Ltd.) and 4-(methylthiobenzoyl)-1-methyl-1-morpholino ethane (Irgacure 907, product name, manufactured by BASF Japan Ltd.), and 2-(dimethylamino)-2-[(4-methylphenyl)methyl]-1-[4-(4-morpholinyl)phenyl]-1-butanone (Irgacure 379, product name, manufactured by BASF Japan Ltd.)

As an oxime ester compound which can be used together, any oxime ester compounds can be used as long as the compound can produce a base material by irradiation. Examples of the oxime ester which may be commercially available include CGI-325, Irgacure OXE01 and Irgacure OXE02 manufactured by BASF Japan Ltd, and N-1919 and NCI-831 manufactured by ADEKA CORPORATION. Also, the compound having two oxime ester groups in the molecule can be preferably used which is described in Japanese Patent No. 4,344,400.

In addition, examples include carbazole oxime ester compounds described in JP2004-359639A, JP2005-097141A, JP2005-220097A, JP2006-160634A, JP2008-094770A, JP2008-509967T, JP2009-040762T and JP2011-80036A.

A base amplifier agent which can further generate a base by decomposition or transfer reaction due to a little amount of the base generated from (A) the base generator can be used together. Examples of the base amplifier agent include a compound having a 9-fluorenylmethyl carbamate bond, a compound having a 1,1-dimethyl-2-cyanomethylcarbamate bond ((CN)CH₂C(CH₃)₂OC(O)NR₂), a compound having a para-nitrobenzylcarbamate bond, a compound having a 2,4-dichlorobenzyl carbamate bond, in addition to those, examples also include a urethane compound described in paragraphs 0010 to 0032 of JP 2000-330270A and a urethane compound described in paragraphs 0033 to 0060 of JP 2008-250111A.

In the resin composition of the present invention, a photopolymerization initiator except for (A) the photobase generator may be used together.

The photopolymerization initiator which can be used together is not particularly limited, for example, a light radical polymerization initiator may be used. As a light radical polymerization initiator, any compounds may be used as long as the compound may provide a radical with light, laser, electron beam, etc., to start the radical polymerization reaction.

Examples of the photopolymerization initiator which can be used together include benzoin and benzoin alkyl ethers such as benzoin, benzoin methyl ether, benzoin ethyl ether and benzoin isopropyl ether; alkyl phenones such as 2-hydroxy-2-methyl-1-phenyl-propan-1-one; acetophenones such as acetophenone, 2,2-dimethoxy-2-phenyl acetophenone, 2,2-diethoxy-2-phenylacetophenone, and 1,1-dichloroacetophenone; aminoacetophenones such as 2-methyl-1-[4-(methylthio)phenyl]-2-morpholinopropan-1-one, 2-benzyl-2-dimethylamino-1-(4-morpholinophenyl)-butan-1-one and N,N-dimethylaminoacetophenone; anthraquinones such as 2-methylanthraquinone, 2-ethylanthraquinone, 2-t-butylanthraquinone and 1-chloroanthraquinone; thioxanthones such as 2,4-dimethylthioxanthone, 2,4-diethylthioxanthone, 2-chlorothioxanthone, and 2,4-diisopropylthioxanthone; ketals such as acetophenone dimethylketal and benzyldimethylketal; 2,4,5-triarylimidazole dimer; riboflavin tetrabutylate; thiol compounds such as 2-mercaptobenzimidazole, 2-mercaptobenzoxazole and 2-mercaptobenzothiazole; organohalogens such as 2,4,6-tris-s-triazine, 2,2,2-tribromoethanol and tribromomethylphenyl sulfone; benzophenones or xanthones such as benzophenone and 4,4′-bisdiethylamino benzophenone; acylphosphine oxides such as 2,4,6-trimethylbenzoyldiphenylphosphine oxide and bis(2,4,6-trimethylbenzoyl)-phenylphosphine oxide; titanocenes such as bis(cyclopentadienyl)diphenyl titanium, bis(cyclopentadienyl)dichlorotitanium, bis(cyclopentadienyl)-bis(2,3,4,5,6-pentafluorophenyl) titanium and bis(cyclopentadienyl)-bis(2,6-difluoro-3-(pyrrol-1-yl)phenyl)titanium.

These well-known conventional photopolymerization initiators can be used alone or as a mixture of two or more, besides, photoinitiating aids such as a tertiary amines such as N,N-dimethyl aminobenzoic acid ethyl ester, N,N-dimethylamino benzoic acid isoamyl ester, pentyl-4-dimethylaminobenzoate, triethylamine and triethanolamine can be added.

Examples of the commercially available photopolymerization initiator include Irgacure 261, 184, 369, 651, 500, 819, 907, 784, 2959, Darocur 1116, 1173, CGI1700, CGI1750, CGI1850, CG-24-61, Lucirin TPO, CGI-784 (product names; manufactured by BASF Japan Ltd.), DAICATII (product names; manufactured by Daicel Chemical Industries Corporation), UVAC1591 (product names; manufactured by Daisel UCB company), Rhodsil photoinitiator 2074 (product names; manufactured by Rhodia, Inc.), Uvecryl P36 (product names; manufactured by UCB S.A.), Ezacure KIP150, KIP65LT, KIP100F, KT37, KT55, KT046, KIP75/B, and ONE (product names; manufactured by Fratelli-Lamberti).

When the other photobase generator except for (A) the photobase generator containing the compound represented by formula (1) and/or the photopolymerization initiator except for (A) the photobase generator are used together, the formulation ratio of the photobase generator and/or the photopolymerization initiator used together is preferably in a range of 0.5 to 10 parts by mass in the resin composition of the present invention of 100 parts by mass.

The resin composition of the present invention may contain a photocopolymerizable monomer within the range where the advantageous effects are not inhibited.

Examples of the photocopolymerizable monomer include alkyl (meth)acrylate such as 2-ethylhexyl (meth)acrylate, cyclohexyl (meth)acrylate; hydroxyalkyl (meth)acrylate such as 2-hydroxyethyl (meth)acrylate, 2-hydroxypropyl (meth)acrylate; mono or di (meth)acrylate of alkyleneoxide derivative such as ethyleneglycol, propyleneglycol, diethyleneglycol, dipropyleneglycol; polyvalent (meth)acrylate of polyvalent alcohol or these ethyleneoxide adducts or propyleneoxide adducts such as hexanediol, trimethylolpropane, pentaerythritol, ditrimethylolpropane, dipentaerythritol, trishydroxyethylisocyanurate; (meth)acrylate of ethyleneoxide adducts or propyleneoxide adducts of phenol such as phenoxyethyl (meth)acrylate, polyethoxydi (meth)acrylate of bisphenol A; (meth)acrylate of glycidylether such as glycerinediglycidylether, trimethylolpropanetriglycidylether, triglycidylisocyanurate; and melamine (meth)acrylate.

The formulation amount of photocopolymerizable monomer is preferably 50% by mass or less, more preferably 30% by mass or less, and further preferably 15% by mass or less on the basis of the solid content except for the solvent of the resin composition. When the formulation amount of photocopolymerizable monomer exceed 50% by mass, warp may be large because of large curing shrinkage. When the photocoploymrizable monomer is derived from (meth)acrylate, the monomer has ether bond. In this case because the ether bond is hydrolyzed by desmear treatment, electric characteristics may deteriorate.

The resin composition of the present invention preferably contains a thermal curing catalyst. Examples of the thermal curing catalyst include imidazole derivatives such as imidazole, 2-methylimidazol, 2-ethylimidazol, 2-ethyl-4-methylimidazol, 2-phenylimidazol, 4-phenylimidazol, 1-cyanoethyl-2-phenylimidazol, 1-(2-cyanoethyl)-2-ethyl-4-methylimidazol; amine compounds such as dicyandiamide, benzildimethylamine, 4-(dimethylamino)-N,N-dimethylbenzilamine, 4-methoxy-N,N-dimethylbenzilamine, 4-methyl-N,N-dimethylbenzilamine; hydrazine compound such as dihydrazide adipate, dihydrazide sebacate; and phosphorus compounds such as triphenylphosphine.

Examples of the commercially available thermal curing catalyst include 2MZ-A, 2MZOK, 2PHZ, 2P4BHZ, and 2P4MHZ (these are all the trade name of imidazole compound manufactured by SHIKOKU CHEMICAL CORPORATION), U-CAT (registered trademark) 3503N, U-CAT3502T (these are all the trade name of blocked isocyanate compound of dimethylamine manufactured by San-Apro Ltd.), DBU, DBN, UCATSA102, U-CAT5002 (these are all bicyclic amidine compound and salt thereof manufactured by San-Apro Ltd.). Thermal curing catalyst is not limited to these and may be used as long as the thermal curing catalyst is the thermal curing catalyst for an epoxy compound or an oxetane compound or accelerate the reaction of an epoxy group and/or an oxetanyl group with carboxy group, and may be used alone or in mixture of two or more.

S-triazine derivative such as guanamine, acetoguanamine, benzoguanamine, melamine, 2,4-diamino-6-metacryloyloxyethyl-S-triazine, 2-vinyl-2,4-diamino-S-triazine, 2-vinyl-4,6-diamino-S-triazine-isocyanuric acid adduct, 2,4-diamino-6-metacryloyloxyethyl-S-triazine-isocyanuric acid adduct may be used, the compound also functioning as adhesion-imparting agent is preferably used as a thermal curing catalyst.

The formulation amount of these thermal curing catalyst is preferably 0.1 to 20 parts by mass, and more preferably 0.5 to 15.0 parts by mass to 100 parts by mass of (C) the thermally reactive compound.

When the energy of active energy ray which permeates the polymer is highly efficiently used for the base generator, namely when the sensitivity of the base generator is required to be improved, the addition of a sensitizer may show advantageous effects. Particularly, the effect provided by the addition of the sensitizer is large, when the components such as (B) the alkali developable resin and (C) the thermally reactive compound also have absorption of light having a wavelength of 360 nm or more. The examples of the compound called a sensitizer include thioxanthone, diethylthioxanthone and the derivatives thereof, a coumarin and the derivatives thereof, a ketocoumarin and the derivatives thereof, a keto-bis-coumarin and the derivative thereof, cyclopentanone and the derivative thereof, cyclohexanone and the derivative thereof, thiopyrylium salt and the derivative thereof, and thioxanthene, xanthene and the derivatives thereof. Specifically, examples of the coumarin, the ketocoumarin and the derivatives thereof include 3,3′-carbonylbiscoumalin, 3,3′-carbonylbis(5,7-dimethoxy coumarin) and 3,3′-carbonylbis(7-acetoxy-coumarin). Specifically, examples of the thioxanthone and the derivatives thereof include diethyl thioxanthone and isopropyl thioxanthone. Furthermore, examples also include benzophenone, acetophenone, phenanthrene, 2-nitrofluorene, 5-nitroacenaphthene, benzoquinone, 2-ethylanthraquinone, 2-tert-butylanthraquinone, 1,2-benz anthraquinone and 1,2-naphthoquinone. One or more of the sensitizer described above showing suitable sensitization may be appropriately selected in view of the structure of the base generator, because the suitable combination of the above sensitizer with the base generator shows particularly advantageous effects.

A solvent may be contained in the resin composition of the present invention.

Examples of the available solvent used widely include ethers such as diethyl ether, tetrahydrofuran, dioxane, ethylene glycol dimethyl ether, ethylene glycol diethyl ether, propylene glycol dimethyl ether, propylene glycol diethyl ether and diethylene glycol dimethyl ether; glycol monoethers (so-called cellosolves) such as ethylene glycol monomethyl ether, ethylene glycol monoethyl ether, propylene glycol monomethyl ether, propylene glycol monoethyl ether, diethylene glycol monomethyl ether and diethylene glycol monoethyl ether; ketones such as methyl ethyl ketone, acetone, methyl isobutyl ketone, cyclopentanone and cyclohexanone; esters such as ethylacetate, butylacetate, n-propylacetate, i-propylacetate, n-butylacetate, i-butylacetate, ester acetate of glycolmonoeters (e.g., methyl cellosolve acetate, ethyl cellosolve acetate), propylene glycol monomethyl ether acetate, propylene glycol monoethyl ether acetate, dimethyl oxalate, methyl lactate and ethyl lactate; alcohols such as ethanol, propanol, butanol, hexanol, cyclohexanol, ethylene glycol, diethylene glycol and glycerin; halogenated hydrocarbons such as methylene chloride, 1,1-dichloroethane, 1,2-dichloroethylene, 1-chloropropane, 1-chlorobutane, 1-chloropentane, chlorobenzene, bromobenzene, o-dichlorobenzene and m-dichlorobenzene; amides such as N,N-dimethylformamide, N,N-diethylformamide, N,N-dimethylacetamide, N,N-diethyl acetamide and N,N-dimethylmethoxyacetamide; pyrrolidones such as N-methyl-2-pyrrolidone and N-acetyl-2-pyrrolidone; lactones such as γ-butyrolactone and α-acetyl-γ-butyrolactone; sulfoxides such as dimethyl sulfoxide; sulfones such as dimethyl sulfone, tetramethylene sulfone and dimethyl tetramethylene sulfone; phosphate amides such as hexamethyl phosphoamide, other organic polarity solvents. Besides, aromatic hydrocarbons such as benzene, toluene, xylene, pyridine, and other organic non-polar solvents may be used. These solvents are used alone or in combination.

The resin composition of the present invention is useful for forming the pattern layer as a permanent coating film of a printed wiring board such as solder resist, cover lay, and interlayer insulating layer, and is particularly useful for forming a solder resist. Because the resin composition of the present invention is excellent in resolution, the resin composition can be suitably used for forming the pattern layer of IC packages where the formation of fine pattern is needed.

### [Pattern Forming Method]

The pattern forming method capable of suitably using the resin composition of the present invention include steps of (a) forming the resin layer obtained from the resin composition on a substrate, (b) activating the photobase generator contained in the resin composition by irradiation in a negative type pattern to cure the irradiated area and (c) removing the unirradiated area by developing to form the negative pattern layer. The irradiated area is cured by generating a base in the irradiated area of the resin composition by the irradiation of the light in a pattern. Then the negative type pattern layer is formed by developing with organic solvent or alkali aqueous solution to remove the unirradiated area.

In the present invention, step (d) of heating the resin layer is preferably added after step (c). Thereby the resin layer is cured sufficiently and the pattern layer further excellent in cure characteristics is obtained.

[Step (a)]

Step (a) is a step of forming the resin layer obtained from the resin composition on a substrate. Examples of the method for forming the resin layer includes a method including applying the liquid resin composition on a substrate and drying, and a method including laminating the dry film obtained from the resin composition on a substrate.

As a method for applying the resin composition on a material, the well-known methods using blade coater, lip coater, comma coater, and film coater can be properly employed. As a drying method, the well-known method such as a method including bringing into contact with hot air in current counter in a dryer and a method including spraying hot air onto a substrate from a nozzle with a device having a vapor heat source, such as hot air circulating drying furnace, IR furnace, hot plate and convection oven can be employed.

As a substrate, the printed wiring substrate and flexible printed wiring substrate having circuit formed in advance, in addition, paper-phenol resin, paper-epoxy resin, glass cloth-epoxy resin, glass cloth-polyimide, glass cloth/nonwoven fabric-epoxy resin, glass cloth/paper-epoxy resin, synthetic fiber-epoxy resin, all grade (FR-4 etc.) copper clad laminated sheet using a composite of fluororesin/polyethylene/PPO/cyanateester etc., polyimide film, PET film, glass substrate, ceramic substrate, wafer substrate, etc. can be used.

[Step (b)]

Step (b) is a step of activating the photobase generator contained in the resin composition by irradiation in a negative type pattern to cure the irradiated area. In step (b), the photobase generator would be destabilized by generation of the base generated in the irradiated area and thereby further base is generated. By chemically proliferating of the base as described above, the deep part of the light irradiated area can be cured sufficiently.

As a light-irradiation device, the direct drawing device capable of irradiating for example, laser light, lamp light, and LED light can be used. As a mask for the irradiation of the light to form the pattern, the negative type mask can be used.

As an active energy ray, the laser light or the scattered light having the maximum wavelength in the range of 350 to 410 nm is preferably used. By making maximum wavelength in the range, the thermal reactivity of the resin composition can be improved efficiently. As long as the laser light has maximum wavelength in the range, any of gas laser and solid-state laser may be used. The amount of irradiation differs depending on the film thickness but can be generally in the range of 100 to 1,500 mJ/cm², and can be preferably in the range of 300 to 1,500 mJ/cm².

As a direct drawing device, the device manufactured by for example, Orbotech Ltd. and PENTAX Ltd can be used and any device oscillating the laser light having the maximum wavelength in the range of 350 to 410 nm can be used.

[Step (c)]

Step (c) is a step of removing the unirradiated area by developing to form the negative pattern layer. Examples of the developing method include the well-known method such as dipping method, shower method, spray method, and brush method. As a developer, potassium hydroxide, sodium hydroxide, sodium carbonate, potassium carbonate, sodium phosphate, sodium silicate, ammonia, amine such as ethanolamine, and alkali aqueous solution such as tetramethylammonium hydroxide (TMAH) aqueous solution or the mixed liquid thereof can be used.

[Step (d)]

The pattern forming method described above preferably further includes step (d) of thermal curing (post-cure) after step (c).

In step (d), the pattern layer is thermally cured sufficiently by the base generated from the photobase generator by step (b). Step (d) can be performed at the curing reaction starting temperature of the unreacted thermally reactive compound or higher. Thereby the pattern layer can be thermally cured sufficiently. The heating temperature is for example, 160° C. or higher.

### EXAMPLES

The present invention now will be described in more detail with reference to Examples, and these Examples are not intended to limit the present invention by any means. Note that “parts” and “%” in the specification is on a mass basis, unless there are special descriptions.

### Synthetic Example 1 (Synthesis of Compound Represented by Formula (1) (Component (A-1)))

Based on Example 6 in JP2017-105749A, the compound (A-1) represented by formula (1) was obtained.

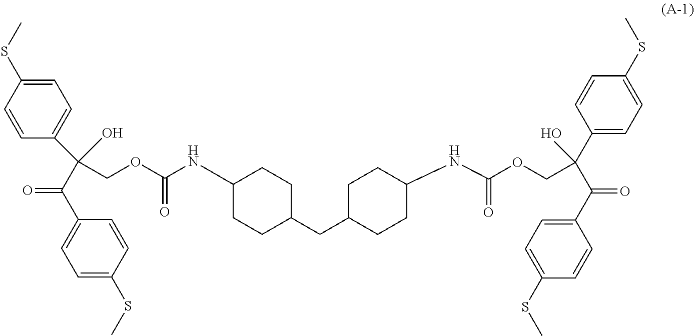 [SMILES: CSc1ccc(C(=O)C(O)(COC(=O)NC2CCC(CC3CCC(NC(=O)OCC(O)(C(=O)c4ccc(SC)cc4)c4ccc(SC)cc4)CC3)CC2)c2ccc(SC)cc2)cc1]

### Synthetic Example 2 (Synthesis of Compound Represented by Formula (1) (Component (A-2)))

(Step 1) Synthesis of Intermediate Compound Represented by Formula (31)

After 1.9 parts of potassium cyanide was dissolved in 10 parts of water and 53 parts of ethanol, the solution was sonicated under nitrogen atmosphere to degas the reaction liquid. To this solution, 10 parts of 4-(methylthio) benzaldehyde represented by the following formula (30) was added dropwise, and the mixture was heated at 80° C. to start the reaction. After stirred for 30 minutes, the reaction liquid was cooled to 3° C., and precipitated crystals were collected by suction filtration. The collected solid was purified by recrystallization using a large amount of ethanol to obtain 7.6 parts of the intermediate compound represented by following formula (31).

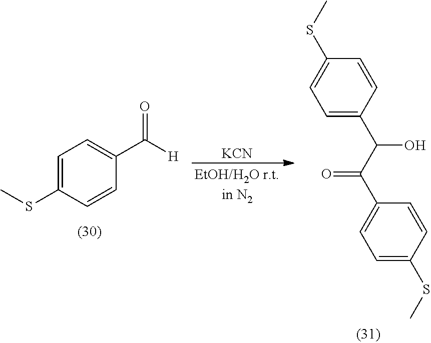

(Step 2) Synthesis of Intermediate Compound Represented by Formula (32)

To a flask equipped with a stirrer, a reflux condenser, and a stirring device, 9.0 parts of paraformaldehyde and 170 parts of dimethyl sulfoxide were added and stirred. Then a solution where 1.4 parts of potassium hydroxide was dissolved in 5 parts of ethanol was added dropwise to the flask, and the mixture was stirred until paraformaldehyde completely dissolved. A solution of 50 parts of the intermediate compound represented by formula (31) obtained in the step 1 dissolved in 30 parts of dimethyl sulfoxide was added dropwise to the dimethyl sulfoxide solution obtained above over 30 minutes, and the mixture was stirred at room temperature for 2 hours. Thereafter, 2.6 parts of 35% hydrochloric acid was added dropwise thereto for neutralization to terminate the reaction. After toluene and saturated saline solution were added to this reaction solution to perform the extraction of the reaction product into the organic layer, the separated and concentrated organic layer was crystallized to obtain 40 parts of the intermediate compound represented by the following formula (32).

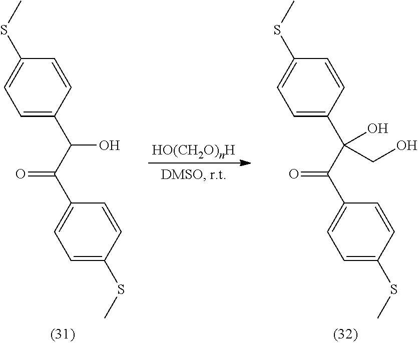 [SMILES: CSc1ccc(C(=O)C(O)c2ccc(SC)cc2)cc1 ; "HO(CH2O)nH" ; CSc1ccc(C(=O)C(O)(CO)c2ccc(SC)cc2)cc1]

(Step 3) Synthesis of Compound of Represented by the Formula (1) (Component (A-2))

10.0 parts of the intermediate compound represented by formula (32) obtained in Step 2, 28 parts of toluene, and 0.08 part of tin octylate were added to a flask and stirred under reflux to homogeneity. Subsequently, 5.6 parts of 2-methacryloyloxyethylisocyanate (Karenz MOI manufactured by Showa Denko K.K.) was added at a liquid temperature of 60° C. After stirring was continued for 3 hours, crystallization was conducted by cooling as to the reaction solution to obtain 10.7 parts of the compound represented by the following formula (A-2).

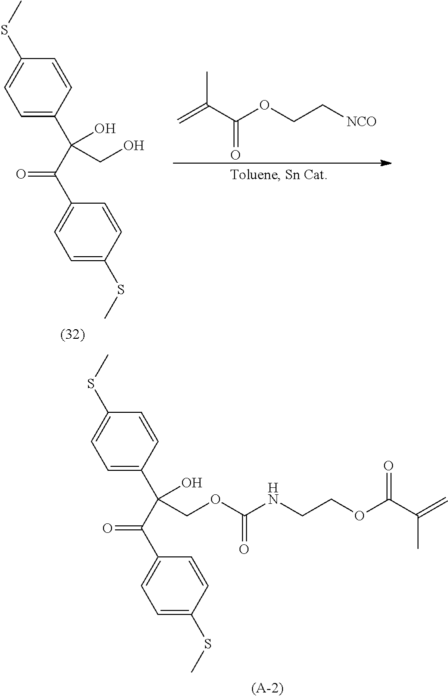

### Examples 1 and 2 and Comparative Example 1 (Preparation of Resin Composition)

The components were prepared in accordance with the amounts listed in the following Table 1, and mixed by a stirrer. The resin compositions of the Examples 1 and 2 and the Comparative Example 1 were prepared. The unit of the values in Table 1 were “parts by mass”

### <Patterning Evaluation>

The resin compositions obtained in Examples 1 and 2 and Comparative Example 1 were applied on the FR-4 substrate pretreated with 5% sulfuric acid with an applicator to form a film having a film thickness of 20 μm. Then, solvent was dried under the conditions of a heating temperature of 80° C. for 30 minutes. By using ultraviolet light irradiator (CS 30L-1 manufactured by GS Yuasa International Ltd.) the composition films obtained above were irradiated with ultraviolet light having energy of 300 mj/cm² through a mask. Next, shower development with 1% sodium carbonate aqueous solution was conducted to form a pattern. Then, the resolution was evaluated by measuring the line width of the pattern formed without residue with a microscope.

### <Storage Stability Evaluation>

The resin compositions obtained in Examples 1 and 2 and Comparative Example 1 were left in the oven at 50° C. and the change in the viscosity with time was measured by a viscometer (TV-20 manufactured by Touki-Sangyo Co., Ltd.) By measuring the rate of increase of the viscosity after 20 hours to the initial viscosity before heating, the storage stability (the rate of viscosity increase) was evaluated. The results were shown in Table 1.

### <Thermal Decomposition Resistance Evaluation>

The resin compositions obtained in Examples 1 and 2 and Comparative Example 1 were applied on rolled copper foils with an applicator to form coated films. Then, the solvent was dried under the conditions of a heating temperature 80° C. for 30 minutes to obtain resin layers having a film thickness of 20 μm. After the resin layers obtained above were irradiated with ultraviolet light having energy of 500 mJ/cm² by using an ultraviolet exposure device (MODEL HMW-680GW manufactured by ORC MANUFACTURING CO., LTD.), the post-cure was conducted at 150° C. for 1 hour to cure the film. Then, by dipping the resin films in iron (III) chloride solution and etching the copper foil, the cured films of the resin compositions of the Examples and the Comparative Example were obtained. The sample piece of 5 mm×5 cm was cut out from the obtained films and set in the viscoelasticity measuring device RSA-G2 manufactured by TA instrument Japan Inc. Tan δ was measured at a frequency of 10 Hz and at a temperature rising speed of 2° C./min in the air atmosphere to obtain the glass transition points (maximum tan δ). The sample of 3 mg was cut out from each cured film and 5% weight reduction temperature (Td5) of the samples was measured by using TGA/DSC1 manufactured by Mettler-Toledo International Inc. in the air flow of 100 ml/min. The results were showed in Table 1.

### <Electrical Properties Evaluation>

From the cured films of the resin compositions of Examples 1 and 2 and Comparative Example 1 obtained by the same process as <Thermal Decomposition Resistance Evaluation> descried above, the sample pieces of 3 mm×8 cm were cut out. The values of the dielectric constant (E) and the dielectric loss tangent (Tan δ) were measured by using a cavity resonator manufactured by Agilent Technologies Japan, Ltd. The results were showed in Table 1.

TABLE 1
Composition of resin composition and evaluation results

| | | | | Comparative |
|---|---|---|---|---|
| | | Example 1 | Example 2 | Example 1 |
| (A) Photobase generator | A-1 | 0.265 | | |
| | A-2 | | 0.265 | |
| | A-3 | | | 0.265 |
| (B) Alkali developable resin | B-1 | 9.5 | | |
| (C) Thermally reactive compound | C-1 | 3.1 | | |
| (D) Photopolymerizable monomer | D-1 | 1.22 | | |
| (E) Thermal curing catalyst | E-1 | 0 | 0 | 0.11 |
| (F) Sensitizer | F-1 | 0 | 0 | 0.011 |

| | | |
|---|---|---|
| (G) Solvent | G-1 | 0.51 |

Evaluation results

| | | | |
|---|---|---|---|
| Patterning perfomance | 50 μm | 50 μm | 50 μm |
| Storage stability (rate of viscocity increase) | 111% | 106% | 417% |
| Glass transition point (Tg) | 131.4 | 130.9 | 130.4 |
| 5% weight reduction temperature (Td5) | 334 | 332 | 334 |
| Dielectric constant (∈) | 2.81 | 2.88 | 2.72 |
| Dielectric loss tangent (Tan δ) | 0.024 | 0.025 | 0.023 |

A-1: The compound represented by formula (1) obtained in Synthetic Example 1
A-2: The compound represented by formula (1) obtained in Synthetic Example 2
A-3: Irgacure907 (manyfactured by BASF Japan Ltd.)
B-1: ZCR-1569H (manufactured by Nippon Kayaku Co., Ltd.)
C-1: YD-134 (manufactured by NIPPON STEEL Chemical & Material Co., Ltd.)
D-1: DPHA (manufactured by Nippon Kayaku Co., Ltd.)
E-1: Triphenylphosphine
F-1: DETX (diethylthioxanthone)
G-1: Diethyleneglycolmonoethyletheracetate

It was showed clearly that the resin compositions of the present invention containing the photobase generator containing the compound represented by formula (1) was excellent in storage stability and the properties of the cured product physical property, too.

### Synthetic Example 3 (Synthesis of Compound Represented by Formula (1) (Component (A-4)))

66 parts of the intermediate compound represented by formula (32) obtained in the step 2, 182 parts of toluene, 2.0 part of triethylamine, and 1.3 parts of dibutylhydroxytoluene (BHT) were added to a flask and stirred to homogeneity at 80° C. Subsequently, 33 parts of 2-isocyanatoethylacrylate (Karenz AOI-VM manufactured by Showa Denko K.K.) was added to the mixture at a temperature of 80° C. After stirring was continued for 3 hours, crystallization was conducted by cooling as to the reaction solution to obtain 86 parts of the compound represented by the following formula (A-4).

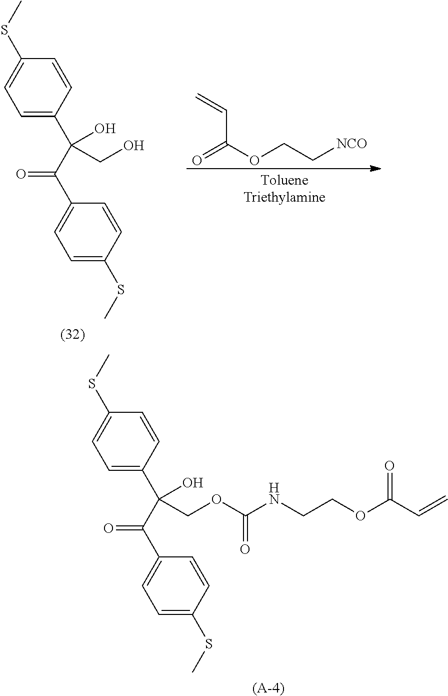

### Synthetic Example 4 (Synthesis of Compound for Comparison (Component (A-5)))

(Step 4) Synthesis of Intermediate Compound Represented by Formula (34)

13.1 parts of N,N′-diisopropylcarbodiimide was added to 11.9 parts of 1,1,3,3-tetramethylguanidine and then the mixture was stirred for 2 hours under heating at 100° C. After the completion of the reaction, hexane was added to the reaction liquid and the mixture was cooled to 5° C. The pieces of precipitated crystal were collected by filtration to obtain 8.3 parts of 1,2-diisoprophyl-4,4,5,5-tetramethylbiguanide (the intermediate compound represented by formula (34)) in the form of a white solid material.

(Step 5) Synthesis of Compound for Comparison (Component (A-5))

7.6 parts of ketoprofen represented by the following formula (33) and 7.2 parts of the intermediate compound represented by formula (34) obtained in step 4 were dissolved in 30 ml of methanol and the mixture was stirred for 30 minutes at room temperature. After the completion of the reaction, the reaction liquid was condensed under reduced pressure. The obtained residues were washed with hexane and then dried under a reduced pressure to obtain 12.2 parts of the compound for comparison represented by the following formula (A-5) in the form of a white solid material.

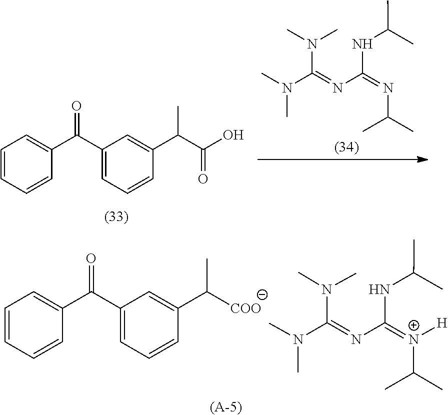

### Example 3 and Comparative Examples 2, 3 and 4 (Preparation of Resin Composition)

The components were prepared in accordance with the amounts listed in the following Table 2 and mixed by a stirrer. The resin compositions of the Example 3 and the Comparative Examples 2, 3 and 4 were prepared. The unit of the values in Table 2 were “parts by mass”

### <Storage Stability Evaluation of B-Stage Dry Film>

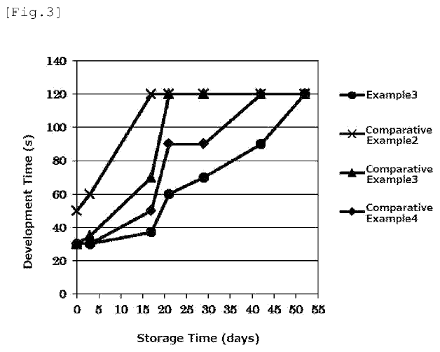

The resin compositions obtained in Example 3 and Comparative Examples 2, 3 and 4 were applied on a rolled copper foils (rolled copper foil BHY-22B-T manufactured by JX Nippon Mining & Metals Corporation) with an applicator (manufactured by BYK Additives & Instruments) to form coated films. Then, solvent was dried in the oven of a heating temperature of 80° C. for 30 minutes to obtain dry films converted into B-stage having a film thickness of 20 μm on the copper foil. These samples were divided into two parts. The one was kept in the thermo-hygrostat of temperature 25° C. and humidity 60% and the other was kept in the refrigerator of temperature of 10° C., respectively. After a predetermined time passes, shower development of the samples with 1% Na₂CO₃ aqueous solution having a temperature of 30° C. was conducted for 2 minutes and the development time (Break time) up to complete the dissolution of the dry film was measured. The results were showed in Table 2, FIG. 2, and FIG. 3. Note that FIG. 2 shows the measurement results of the samples kept under the conditions of a temperature 25° C. and a humidity of 60%, and FIG. 3 shows the measurement results of the samples kept under the conditions of a temperature of 10° C.

TABLE 2
Composition of resin composition and evaluation results

| | | | Comparative | Comparative | Comparative |
|---|---|---|---|---|---|
| | | Example 3 | Example 2 | Example 3 | Example 4 |
| (A) Photobase generator | A-4 | 0.087 | | | |
| | A-5 | | 0.087 | | |
| | A-3 | | | 0.087 | 0.087 |
| (B) Alkali developable resin | B-2 | 2 | | | |
| (C) Thermally reactive compound | C-1 | 1 | | | |
| (D) Photopolymerizable monomer | D-1 | 0.4 | | | |
| (E) Thermal curing catalyst | E-1 | | | 0.007 | |
| (F) Sensitizer | F-1 | | | 0.003 | 0.003 |

| | | |
|---|---|---|
| (G) Solvent | G-1 | 0.73 |

Evaluation results

| Storage condition | Storage days until development time needs 2 or more minutes | | | |
|---|---|---|---|---|
| 25° C., humidity 60% | 7 | 1 | 4 | 7 |
| 10° C. | 52 | 15 | 20 | 42 |

A-4: The compound represented by formula (1) obtained in Synthetic Example 3
A-5: The compound for comparison obtained in Synthetic Example 4
A-3: Irgacure907 (manyfactured by BASF Japan Ltd.)
B-2: ZAR-2001H (manufactured by Nippon Kayaku Co., Ltd.)
C-1: YD-134 (manufactured by NIPPON STEEL Chemical & Material Co., Ltd.)
D-1: DPHA ((manufactured by Nippon Kayaku Co., Ltd.)
E-1: Triphenylphosphine
F-1: DETX (diethylthioxanthone)
G-1: Diethyleneglycolmonoethyletheracetate

### INDUSTRIAL APPLICABILITY

The resin composition of the present invention is useful for forming the pattern layer as a permanent coating film of a printed wiring board such as solder resist, cover lay, and interlayer insulating layer and is particularly useful for forming a solder resist. Because the resin composition of the present invention is excellent in resolution, the resin composition of the present invention can be suitably used for forming the pattern layer of IC packages where the fine pattern forming is demanded.

1-6. (canceled)

7. A resin composition comprising (A) a photobase generator containing a compound represented by a following chemical formula (1): 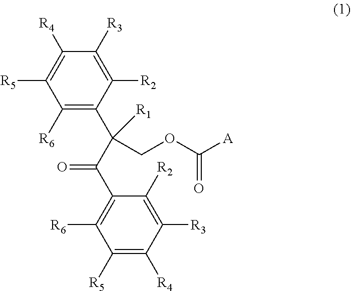
wherein in formula (1), R₁ represents a hydrogen atom, a hydroxy group, an alkoxy group or an organic group other than the aforementioned substituents; R₂, R₃, R₅ and R₆ each independently represent a hydrogen atom, halogen atom, hydroxy group, alkoxy group, mercapto group, sulfide group, silyl group, silanol group, nitro group, nitroso group, cyano group, sulfino group, sulfo group, sulfonato group, phosphino group, phosphinyl group, phosphono group, phosphonato group, amino group, ammonio group or an organic group other than the aforementioned substituents, each of R₂, R₃, R₅ and R₆ plurally existing may be the same or different from each other; R₂ and R₃ on the same benzene ring may be connected to form a ring structure and R₅ and R₆ on the same benzene ring may be connected to form a ring structure; R₄ each independently represents a hydrogen atom or an organic group having a thioether bond, and at least one of R₄ is the organic group having a thioether bond; the organic group having a thioether bond represented by R₄ and R₃ or R₅ may be connected to form a ring structure; A is a substituent having a formula (1-1): 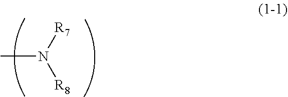
wherein in formula (1-1), R₇ and R₈ each independently represent a hydrogen atom or a linear or a branched alkyl group having a carbon number of 2 to 6 or a heterocyclic group, or R₇ and R₈ may be connected to form a heterocyclic structure, (B) an alkali developable resin, and (C) a thermally reactive compound.

8. The resin composition according to claim 7, wherein the resin composition can provide negative pattern formed by conducting alkali-developing after selective irradiation of the light and subsequent heating to the resin composition to provide addition reaction of (B) the alkali developable resin with (C) the thermally reactive compound.

9. A dry film obtained from the resin composition according to claim 7.

10. A cured product of the resin composition according to claim 7.

11. A cured product of the dry film according to claim 9.

12. A printed wiring board comprising the cured product according to claim 10.

13. The resin composition according to claim 7, wherein in (A) the photobase generator containing the compound represented by the formula (1), R₇ and R₈ of the formula (1-1) each independently represent a hydrogen atom, ethyl group or heterocyclic group, or R₇ and R₈ may be connected to form a heterocyclic structure.
